(19) United States
(12) Patent Application Publication
(10) Pub. No.: US 2007/0128843 A1
(43) Pub. Date: Jun. 7, 2007

(54) Manufacturing method of workpiece

(75) Inventors: Yukihisa Takeuchi, Chita-gun (JP); Kenso Kanada, Chiryu-city (JP); Kazumasa Watabe, Kariya-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/634,478

(22) Filed: Dec. 6, 2006

(30) Foreign Application Priority Data
Dec. 7, 2005 (JP) 2005-352862
Oct. 17, 2006 (JP) 2006-282529

(51) Int. Cl. H01L 21/44

(52) U.S. Cl. 438/597; 438/612

(57) ABSTRACT

A fused coating material is injected from a nozzle onto a copper foil, the temperature of which is lower than a fusion start temperature of the coating material, and the thus injected coating material is coagulated so as to form a mask on the copper foil. According to a mask pattern of the mask composed of the coagulated coating material, the copper foil is etched for patterning. After that, the coating material, which is the mask, is heated and fused so as to remove the coating material, which is the mask, from the copper foil.

### BACKGROUND OF THE INVENTION

1. Field of the Invention

The present invention relates to a manufacturing method of a workpiece in which a mask is formed on a workpiece to be worked by a coating material, which is fused and coagulated according to a temperature, and patterning is conducted according to a mask pattern formed by this mask.

2. Description of the Related Art

A conventional method of forming an ink pattern on a board is disclosed, for example, in the official gazette of JP-A-8-34156. As shown in this Patent Document 1, a method of forming a desired pattern is generally executed by making exposure. A method of forming a wiring pattern on a printed board by a common exposure method will be explained below.

First of all, a printed board, on which copper foil is provided, is prepared. Then, the copper foil is uniformly coated with a photo-resist-film. After that, when exposure is conducted on the copper foil by an exposure machine, the photo-resist-film is patterned. Specifically, the photo-resist-film, which is provided on an unnecessary portion of the copper foil, is made to be fragile. Alternatively, a portion of the copper foil, which will become a wiring portion, is hardened. In this way, patterning is conducted on the photo-resist-film.

Successively, the fragile portion of the photo-resist-film or the portion of the photo-resist-film, which is not hardened, is resolved and decomposed. Due to the foregoing, a portion of the copper foil to be etched is exposed. Then, the copper foil in the portion, the photo-resist-film of which is open, is etched with a solution of ferric chloride so as to remove the photo-resist-film. In this way, a wiring pattern is formed on the printed wiring board.

By the process described above, it is possible to form a printed board having one wiring layer. When the above process is repeated, it is possible to form a laminated printed board.

However, according to the above prior art, the following problems may be encountered. After the photo-resist-film has been patterned by means of exposure, an unnecessary portion of the photo-resist-film is removed by an organic solvent. Then, the photo-resist-film, which has been left on the copper foil, is spread and oozed out by the organic solvent onto the portion from which the photo-resist-film has been removed. Due to the foregoing, a line width on the photo-resist-film, which has been formed by patterning, is extended. Therefore, when the copper foil is etched in this state, the line width of the wiring is extended corresponding to the spread of the photo-resist-film.

Recently, there has been a tendency that the line width of the wiring formed on the printed board is reduced. At present, the line width is approximately 50 μm. It is estimated that the line width will be further reduced in the future. However, when the photo-resist-film is spread and the line width is extended as described above at the time making a pattern on the photo-resist-film, it is impossible to form a highly accurate wiring, the line width of which is accurate, on the printed board.

In this connection, a patterning method is executed in which drawing is conducted on a photo-resist-film by an electron beam. However, according to this method, since an unnecessary portion of the photo-resist-film is removed by an organic solvent, it is impossible to form an accurate wiring, the line width of which is highly accurate, in the same manner as that described before.

### SUMMARY OF THE INVENTION

In view of the above points, it is a first object of the present invention to provide a manufacturing method of a workpiece capable of forming a highly accurate mask on the workpiece and also capable of conducting a highly accurate patterning on the workpiece with the mask. A second object of the present invention is to provide a manufacturing method of a workpiece capable of directly drawing a desired pattern on the workpiece without using a mask.

In order to accomplish the above objects, according to the first characteristic of the present invention, a fused coating material is injected from a nozzle (50) onto a workpiece (10, 60, 90, 95), the temperature of which is lower than a fusion start temperature of the coating material (40), so as to coat the coating material on the workpiece and the thus injected coating material is coagulated. In this way, a mask-pattern-shaped mask is formed on the workpiece. According to the mask, the workpiece is patterned. After that, the mask is heated and fused so that the mask can be removed from the workpiece.

According to this manufacturing method, the fused coating material can be coagulated simultaneously when it is coated on the workpiece. Accordingly, it is possible to prevent the coating material from spreading and oozing out. That is, a difference between the fusion temperature and the coagulation temperature of the coating material is not more than 5° C. Therefore, when the heated and fused coating material is coated on the workpiece, the temperature of which is lower than the temperature of the fused coating material only by 5° C., the coating material is coagulated simultaneously when it is coated. Due to the foregoing, it is possible to form a highly accurate mask on the workpiece. According to this mask, the workpiece can be highly accurately patterned.

According to the second characteristic of the present invention, a powder-shaped coating material (40) is spread on a surface of the workpiece (10, 60). A portion of the thus spread powder-shaped coating material, which is located at a position to become a mask, is locally heated and fused. At this time, when a position to be locally heated is moved, the coating material located at the position where heating has been conducted is coagulated so that the mask can be formed. Then, the powder-shaped coating material left on the workpiece is removed and the workpiece is patterned according to the mask-pattern of the mask. Then, the mask is heated and fused so that the mask can be removed from the workpiece.

According to this manufacturing method, only the power-shaped coating material, which is located in the portion which will become the mask, is heated, fused and coagulated. Therefore, it is possible to prevent the locally heated coating material from spreading and oozing out. That is, simultaneously when the heating of the locally heated powder-shaped coating material is stopped, the powder-shaped coating material is coagulated. Due to the foregoing, it is possible to form a highly accurate mask on the workpiece. According to this mask, the workpiece can be highly accurately patterned.

Concerning the coating material used for the above manufacturing process, it is possible to use a coating material in which a difference between the fusion start temperature and the fusion end temperature is not more than 5° C. It is preferable to fuse and coagulate the coating material by a small difference in the temperature. Specifically, it is preferable that the difference in the temperature be 2° C.

In the above case, when a solder-material, in which a solder is added into a coating material, is coagulated on the workpiece being formed into a dot-shape, that is, when a solder material is made to reflow, a solder bump (30) can be provided on the workpiece. Due to the foregoing, the other electronic parts and wires can be electrically connected to the workpiece through the solder.

In the above case, in the case where the workpiece (10, 60) is a printed board (10) and a through-hole (11) is formed on the printed board, when the fused coating material is injected into an opening portion of the through-hole, it is possible to close the opening portion of the through-hole with the coating material. Therefore, it is possible to prevent foreign objects from entering the through-hole. Further, since the coating material can be fused and coagulated only by a difference in the temperature not more than 5° C., in the case where a lid portion becomes unnecessary, the lid portion can be easily removed only when the temperature is raised.

Further, in the above case, when the fused coating material is injected into the through-hole and coagulated, the through-hole can be filled and closed with the coating material. Therefore, it is possible to prevent foreign objects from entering the through-hole. Further, only when heating is conducted, the coagulated coating material can be easily removed from the through-hole.

According to the third characteristic of the present invention, a drawing sheet (100), on which a coating material (40) is coated on a sheet member (200), is prepared. Then, the drawing sheet is arranged on a workpiece so that the workpiece (60) and the coating material can be opposed to each other. Next, only the sheet member is removed from the drawing sheet. Then, a portion of the coating material on the workpiece, which becomes a mask, is locally heated and fused and the thus locally heated portion is moved so that the coating material, which has been located at the heated position, can be coagulated. In this way, a mask-pattern-shaped mask is formed. After that, according to the mask, the workpiece is patterned. The mask is heated and fused so that it can be removed from the workpiece.

Due to the foregoing, only a portion of the coating material, which becomes the mask, is heated, fused and coagulated. Therefore, the locally heated coating material can be prevented from spreading and oozing out. Accordingly, it is possible to form a highly accurate mask. Due to the foregoing, the workpiece can be highly accurately patterned.

According to the fourth characteristic of the present invention, a drawing sheet (110) is prepared on which a coating material (42) containing a solder material is coated on a sheet member (200). Then, the drawing sheet is arranged on a workpiece so that the workpiece (20, 60) and the coating material can be opposed to each other. Then, only the sheet member is removed from the drawing sheet. Successively, a portion of the coating material, in which a solder bump (30) is going to be formed, is locally, directly heated and fused. In this way, the coating material containing the solder material is temporarily fixed to the workpiece. After that, when the coating material on the workpiece is subjected to heat treatment, the solder material contained in the coating material is fixed to the work piece and the solder bump can be formed.

As described above, when the coating material containing the solder material is directly heated, the solder bump can be directly drawn on the workpiece. That is, it is possible to form a highly accurate solder bump without using a mask for forming the solder bump.

In this case, when the coating material containing the solder material is temporarily fixed, a portion of the coating material containing the solder material, which has not been locally heated, can be removed. Due to the foregoing, any unnecessary part can be removed from the workpiece and heat treatment can be conducted.

Further, after the solder bump has been formed on the workpiece, a drawing sheet (100) is prepared on which a coating material (40) not containing solder material is coated on a sheet member (200). Then, the drawing sheet is arranged on the workpiece so that the workpiece and the coating material not containing solder material can be opposed to each other and only the sheet member is removed from the drawing sheet. When a portion of the coating material, which becomes a mask, is locally and directly heated and fused so that the solder bump can be wrapped by the portion of the coating material and at the same time the portion to be locally heated is moved, the coating material in the heated portion is coagulated and a mask of the mask-shaped pattern is formed. After that, according to this mask, the workpiece is patterned to a wiring pattern. The mask is heated and fused so that the mask can be removed from the workpiece.

As described above, after the solder bump has been formed on the workpiece, the coating material is temporarily fixed so that the solder bump can be wrapped by the coating material and the mask can be formed on the workpiece. By the mask concerned, the workpiece can be patterned. According to this method, the pattern (the wiring pattern), on which the solder bump is formed, can be formed by steps, the number of which is small.

According to the fifth characteristic of the present invention, a drawing sheet (110) is prepared on which a coating material (42) containing a solder material is coated on a sheet member (200). Then, the drawing sheet is arranged on a workpiece so that the workpiece (20, 60) and the coating material can be opposed to each other. Successively, from the opposite side of the coating material in the sheet member, a portion of the coating material, in which the solder bump is going to be formed, is directly heated and fused and the coating material containing the solder material is temporarily fixed to the workpiece. When the coating material is subjected to heat treatment, the solder material contained in the coating material is fixed to the workpiece so as to form the solder bump. Even by this method, the solder bump can be directly drawn on the workpiece.

According to the sixth characteristic of the present invention, only the sheet member is removed from the drawing sheet, and the solder bump is formed. When the sheet member is removed as described above and the coating material is directly heated, the coating material can be highly accurately heated.

In this case, when the sheet member is moved, a portion of the coating material, which is not heated, is moved to a position where the solder bump is going to be formed and the coating material can be temporarily fixed to a position where the solder bump concerned is going to be formed. Due to the foregoing, the coating material provided on the sheet member can be effectively utilized.

In the case where the coating material is heated, when laser beams irradiated from the semiconductor laser (80, 82, 84, 86, 88) are condensed to the coating material by the condenser lens (81, 83, 85, 87, 89), the coating material concerned can be locally heated.

In this case, a difference between the fusion start temperature and the fusion end temperature of the coating material can be in the range from 18° C to 100° C.

When the temperature range is provided as described above, a mask can be formed on the workpiece in accordance with the material of the workpiece to be worked. In order to realize the range from 18° C. to 100° C. described above, it is preferable that paraffin or, polyethylene glycol be added with powder material such as alumina, carbon, iron, SUS (stainless steel), SiC, Si or silicon nitride.

A principal component of the coating material may be paraffin or polyethylene glycol.

When the principal component of the coating material is paraffin or polyethylene glycol as described above and when the purity of paraffin or polyethylene glycol is enhanced, a difference between the fusion start temperature and the fusion end temperature can be reduced. Therefore, the difference between the fusion start temperature and the fusion end temperature can be realized at a value not more than 5° C. In this connection, in order to cause the fusion and coagulation of the coating material at a small difference in the temperature, it is preferable that the difference between the fusion start temperature and the fusion end temperature be 2° C.

Concerning paraffin to be used here, it is possible to use paraffin shown in items (1) to (5) described below in which normal paraffin and non-normal paraffin are combined with each other. In this connection, the composition ratio % is expressed by weight %. It is preferable that the difference between the fusion start temperature and the fusion end temperature of paraffin be not more than 5° C. as described later. It is more preferable that the difference between the fusion start temperature and the fusion end temperature of paraffin be smaller than that. In the following items, small temperature differences are shown.

(1) Paraffin in which a total of the component of normal paraffin is 88.99% and the remainder is non-normal paraffin.

“The Composition of Normal Paraffin”

Normal paraffin with carbon number 18: 0.08%
Normal paraffin with carbon number 19: 0.41%
Normal paraffin with carbon number 20: 1.76%
Normal paraffin with carbon number 21: 5.61%
Normal paraffin with carbon number 22: 10.66%
Normal paraffin with carbon number 23: 14.76%
Normal paraffin with carbon number 24: 14.50%
Normal paraffin with carbon number 25: 12.42%
Normal paraffin with carbon number 26: 9.08%
Normal paraffin with carbon number 27: 6.58%
Normal paraffin with carbon number 28: 4.04%
Normal paraffin with carbon number 29: 2.88%
Normal paraffin with carbon number 30: 2.09%
Normal paraffin with carbon number 31: 1.50%
Normal paraffin with carbon number 32: 1.02%
Normal paraffin with carbon number 33: 0.72%
Normal paraffin with carbon number 34: 0.37%
Normal paraffin with carbon number 35: 0.24%
Normal paraffin with carbon number 36: 0.14%
Normal paraffin with carbon number 37: 0.08%
Normal paraffin with carbon number 38: 0.05%

The total of the normal paraffin components is 88.99% and the remainder is non-normal paraffin components.

The average carbon number of paraffin of the above composition (1) is 24.74. The standard deviation of the molecular weight distribution is 2.86. The smaller the standard deviation is, the sharper the molecular weight distribution becomes. The maximum molecular weight of paraffin of the composition (1) is 534. The minimum molecular weight of paraffin of the composition (1) is 254. Accordingly, the molecular weight distribution range is 280.

The fusion start temperature of paraffin of the composition (1) is 50.4° C. and the fusion end temperature of paraffin of the composition (1) is 51.7° C. Accordingly, the difference between the fusion start temperature and the fusion end temperature can be set at a very low value of 1.3° C.

(2) Paraffin in which a total of the component of normal paraffin is 88.64% and the remainder is non-normal paraffin.

“The Composition of Normal Paraffin”

Normal paraffin with carbon number 18: 0.07%
Normal paraffin with carbon number 19: 0.28%
Normal paraffin with carbon number 20: 1.10%
Normal paraffin with carbon number 21: 3.38%
Normal paraffin with carbon number 22: 6.92%
Normal paraffin with carbon number 23: 10.86%
Normal paraffin with carbon number 24: 12.67%
Normal paraffin with carbon number 25: 12.74%
Normal paraffin with carbon number 26: 11.17%
Normal paraffin with carbon number 27: 9.18%
Normal paraffin with carbon number 28: 6.43%
Normal paraffin with carbon number 29: 4.73%
Normal paraffin with carbon number 30: 3.01%
Normal paraffin with carbon number 31: 2.16%
Normal paraffin with carbon number 32: 1.42%
Normal paraffin with carbon number 33: 0.98%
Normal paraffin with carbon number 34: 0.55%
Normal paraffin with carbon number 35: 0.36%
Normal paraffin with carbon number 36: 0.22%
Normal paraffin with carbon number 37: 0.15%
Normal paraffin with carbon number 38: 0.11%
Normal paraffin with carbon number 39: 0.09%
Normal paraffin with carbon number 40: 0.06%

The total of the normal paraffin components is 88.64% and the remainder is non-normal paraffin components.

The average carbon number of paraffin of the above composition (2) is 25.61. The standard deviation of the molecular weight distribution is 3.05. The maximum molecular weight of paraffin of the composition (2) is 562. The minimum molecular weight of paraffin of the composition (2) is 254. Accordingly, the molecular weight distribution range is 366. The fusion start temperature of paraffin of the composition (2) is 52.5° C. and the fusion end temperature of paraffin of the composition (2) is 53.7° C. Accordingly, the difference between the fusion start temperature and the fusion end temperature can be set at a very low value of 1.2° C.

(3) Paraffin in which a total of the component of normal paraffin is 89.57% and the remainder is non-normal paraffin.

“The Composition of Normal Paraffin”

Normal paraffin with carbon number 19: 0.09%
Normal paraffin with carbon number 20: 0.34%
Normal paraffin with carbon number 21: 1.31%
Normal paraffin with carbon number 22: 3.50%
Normal paraffin with carbon number 23: 7.09%
Normal paraffin with carbon number 24: 10.36%
Normal paraffin with carbon number 25: 12.57%
Normal paraffin with carbon number 26: 12.68%
Normal paraffin with carbon number 27: 11.75%
Normal paraffin with carbon number 28: 8.80%
Normal paraffin with carbon number 29: 6.99%
Normal paraffin with carbon number 30: 4.74%
Normal paraffin with carbon number 31: 3.41%
Normal paraffin with carbon number 32: 2.42%
Normal paraffin with carbon number 33: 1.70%
Normal paraffin with carbon number 34: 0.93%
Normal paraffin with carbon number 35: 0.54%
Normal paraffin with carbon number 36: 0.25%
Normal paraffin with carbon number 37: 0.10%

The total of the normal paraffin components is 89.57% and the remainder is non-normal paraffin components.

The average carbon number of paraffin of the above composition (3) is 26.56. The standard deviation of the molecular weight distribution is 2.94. The maximum molecular weight of paraffin of the composition (3) is 520. The minimum molecular weight of paraffin of the composition (3) is 268. Accordingly, the molecular weight distribution range is 252. The fusion start temperature of paraffin of the composition (3) is 54.6° C. and the fusion end temperature of paraffin of the composition (3) is 55.6° C. Accordingly, the difference between the fusion start temperature and the fusion end temperature can be set at a very low value of 1.0° C.

(4) Paraffin in which a total of the component of normal paraffin is 71.11% and the remainder is non-normal paraffin.

“The Composition of Normal Paraffin”

Normal paraffin with carbon number 23: 0.08%
Normal paraffin with carbon number 24: 0.16%
Normal paraffin with carbon number 25: 0.39%
Normal paraffin with carbon number 26: 0.87%
Normal paraffin with carbon number 27: 1.52%
Normal paraffin with carbon number 28: 1.99%
Normal paraffin with carbon number 29: 2.68%
Normal paraffin with carbon number 30: 3.14%
Normal paraffin with carbon number 31: 3.71%
Normal paraffin with carbon number 32: 3.94%
Normal paraffin with carbon number 33: 4.07%
Normal paraffin with carbon number 34: 4.37%
Normal paraffin with carbon number 35: 4.94%
Normal paraffin with carbon number 36: 5.49%
Normal paraffin with carbon number 37: 6.00%
Normal paraffin with carbon number 38: 5.44%
Normal paraffin with carbon number 39: 4.50%
Normal paraffin with carbon number 40: 3.71%
Normal paraffin with carbon number 41: 3.01%
Normal paraffin with carbon number 42: 2.53%
Normal paraffin with carbon number 43: 1.94%
Normal paraffin with carbon number 44: 1.55%
Normal paraffin with carbon number 45: 1.06%
Normal paraffin with carbon number 46: 0.84%
Normal paraffin with carbon number 47: 0.58%
Normal paraffin with carbon number 48: 0.45%
Normal paraffin with carbon number 49: 0.33%
Normal paraffin with carbon number 50: 0.32%
Normal paraffin with carbon number 51: 0.26%
Normal paraffin with carbon number 52: 0.21%
Normal paraffin with carbon number 53: 0.19%
Normal paraffin with carbon number 54: 0.17%
Normal paraffin with carbon number 55: 0.15%
Normal paraffin with carbon number 56: 0.13%
Normal paraffin with carbon number 57: 0.11%
Normal paraffin with carbon number 58: 0.09%
Normal paraffin with carbon number 59: 0.08%
Normal paraffin with carbon number 60: 0.06%
Normal paraffin with carbon number 61: 0.05%

The total of the normal paraffin components is 71.11% and the remainder is non-normal paraffin components.

The average carbon number of paraffin of the above composition (4) is 36.34. The standard deviation of the molecular weight distribution is 5.70. The maximum molecular weight of paraffin of the composition (4) is 856. The minimum molecular weight of paraffin of the composition (4) is 324. Accordingly, the molecular weight distribution range is 532. The fusion start temperature of paraffin of the composition (4) is 72.1° C. and the fusion end temperature of paraffin of the composition (4) is 73.4° C. Accordingly, the difference between the fusion start temperature and the fusion end temperature can be set at a very low value of 1.3° C.

(5) Paraffin in which a total of the component of normal paraffin is 75.78% and the remainder is non-normal paraffin.

“The Composition of Normal Paraffin”

Normal paraffin with carbon number 29: 0.08%
Normal paraffin with carbon number 30: 0.23%
Normal paraffin with carbon number 31: 0.69%
Normal paraffin with carbon number 32: 1.36%
Normal paraffin with carbon number 33: 1.77%
Normal paraffin with carbon number 34: 2.02%
Normal paraffin with carbon number 35: 2.21%
Normal paraffin with carbon number 36: 2.41%
Normal paraffin with carbon number 37: 3.02%
Normal paraffin with carbon number 38: 3.58%
Normal paraffin with carbon number 39: 3.52%
Normal paraffin with carbon number 40: 3.94%
Normal paraffin with carbon number 41: 4.13%
Normal paraffin with carbon number 42: 5.15%
Normal paraffin with carbon number 43: 4.95%
Normal paraffin with carbon number 44: 5.54%
Normal paraffin with carbon number 45: 4.55%
Normal paraffin with carbon number 46: 4.71%
Normal paraffin with carbon number 47: 3.53%
Normal paraffin with carbon number 48: 3.08%
Normal paraffin with carbon number 49: 2.38%
Normal paraffin with carbon number 50: 2.16%
Normal paraffin with carbon number 51: 1.68%
Normal paraffin with carbon number 52: 1.35%
Normal paraffin with carbon number 53: 1.21%
Normal paraffin with carbon number 54: 1.00%
Normal paraffin with carbon number 55: 0.85%
Normal paraffin with carbon number 56: 0.80%
Normal paraffin with carbon number 57: 0.63%
Normal paraffin with carbon number 58: 0.59%
Normal paraffin with carbon number 59: 0.49%
Normal paraffin with carbon number 60: 0.41%
Normal paraffin with carbon number 61: 0.34%
Normal paraffin with carbon number 62: 0.38%
Normal paraffin with carbon number 63: 0.36%
Normal paraffin with carbon number 64: 0.30%
Normal paraffin with carbon number 65: 0.23%
Normal paraffin with carbon number 66: 0.15%

The total of the normal paraffin components is 75.78% and the remainder is non-normal paraffin components.

The average carbon number of paraffin of the above composition (5) is 43.69. The standard deviation of the molecular weight distribution is 6.81. The maximum molecular weight of paraffin of the composition (5) is 926. The minimum molecular weight of paraffin of the composition (5) is 408. Accordingly, the molecular weight distribution range is 518. The fusion start temperature of paraffin of the composition (5) is 86.2° C. and the fusion end temperature of paraffin of the composition (5) is 87.9° C. Accordingly, the difference between the fusion start temperature and the fusion end temperature can be set at a very low value of 1.7° C.

Concerning polyethylene glycol, the following may be used. For example, with respect to polyethylene glycol, the mean molecular weight of which is 1540, the fusion start temperature is 46° C. and the fusion end temperature is 47.2° C. Accordingly, a difference between the fusion start temperature and the fusion end temperature can be set at a very low value of 1.2° C.

With respect to polyethylene glycol, the mean molecular weight of which is 4000, the maximum value of the molecular weight is 5464, the minimum value of the molecular weight is 1689, the number mean molecular weight Mn is 2866, the weight mean molecular weight Mw is 2935, Z mean molecular weight Mz is 3004, the molecular weight dispersion (The closer to 1 the molecular weight dispersion is, the sharper the distribution becomes.) Mw/Mn is 1.0238, and Mz/Mw is 1.0237. With respect to this polyethylene glycol, the mean molecular weight of which is 4000, the fusion start temperature is 55.1° C. and the fusion end temperature is 56.4° C. Accordingly, a difference between the fusion start temperature and the fusion end temperature can be set at a very low value of 1.3° C.

Incidentally, the reference numerals in parentheses, to denote the above means, are intended to show the relationship of the specific means which will be described later in an embodiment of the invention.

The present invention may be more fully understood from the description of preferred embodiments of the invention set forth below, together with the accompanying drawings.

### BRIEF DESCRIPTION OF THE DRAWINGS

FIG. 1 is a sectional view showing a printed board formed by the manufacturing method of the present invention.

FIGS. 2A to 2D are views showing a manufacturing process of forming a wiring pattern by a method of printing with a printer.

FIG. 3 is a view showing a manufacturing process successively conducted after the process shown in FIGS. 2A to 2D.

FIGS. 4A to 4C are views showing a manufacturing process of drawing a wiring pattern of coating material on copper foil by a manufacturing method of the second embodiment of the present invention.

FIGS. 5A to 5D are views showing a state in which a metallic block is worked while the metallic block is being masked with coating material.

FIG. 6 is a view showing a state in which coating material is filled into a through-hole on a printed board.

FIGS. 7A to 7D are views showing a state in which a sphere is worked while the sphere is being masked with coating material.

FIGS. 8A to 8E are views showing a manufacturing process of drawing a wiring pattern of coating material on copper foil of a printed board by a manufacturing method of the fourth embodiment of the present invention.

FIGS. 9A to 9D are views showing a manufacturing process of drawing a solder bump and a wiring pattern of coating material on copper foil on a printed board by a manufacturing method of the fifth embodiment of the present invention.

FIGS. 10A to 10C are views showing a manufacturing process successively conducted after the process shown in FIGS. 9A to 9D.

FIGS. 11A to 11D are views showing a manufacturing process of forming a solder bump on a wiring pattern in the sixth embodiment.

FIGS. 12A to 12C are views showing a manufacturing process of forming a solder bump on a wiring pattern in the seventh embodiment.

FIGS. 13A to 13C are views showing a manufacturing process of forming a solder bump on a wiring pattern in the eighth embodiment.

FIGS. 14A to 14C are views showing a state in which a coating material 42 is temporarily fixed with a different semiconductor laser, wherein FIG. 14A is a view showing a state in which a portion of the coating material, which becomes a solder bump, is temporarily fixed to a fine wiring pattern, FIG. 14B is a view showing a state in which a portion of the coating material, which becomes a solder bump, is temporarily fixed to a bus-bar, and FIG. 14C is a view showing a state in which a portion of the coating material, which becomes a solder bump, is temporarily fixed to a wide range of the bus-bar.

FIGS. 15A and 15B are views showing a manufacturing process of forming a solder bump with a large semiconductor laser in the tenth embodiment of the present invention.

### DESCRIPTION OF THE PREFERRED EMBODIMENTS

Referring to the drawings, embodiments of the present invention will be explained below. In this connection, like reference characters are used to indicate like parts in the accompanying drawings of the embodiments.

Referring to the drawings, the first embodiment of the present invention will be explained as follows.

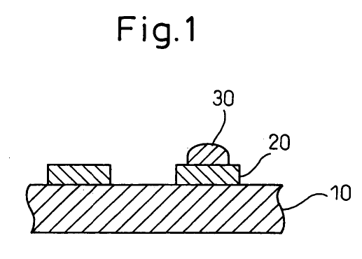

FIG. 1 is a sectional view showing a printed board formed by the manufacturing method of the present invention. As shown in the view, a wiring 20 is formed on a printed board 10. On this wiring 20, a solder bump 30 is provided. In this embodiment, the size of the printed board 10 is 300 mm×300 mm. In some cases, the size of the printed board 10 is 1000 mm×1000 mm. The wiring 20 is formed out of copper foil. For example, the width of the wiring 20 is 30 μm to 50 μm and the thickness of the wiring 20 is several μm. The solder bump 30 is used for electrically connecting electronic parts, which are mounted on the printed board 10, with wires or leads which are connected to an external device.

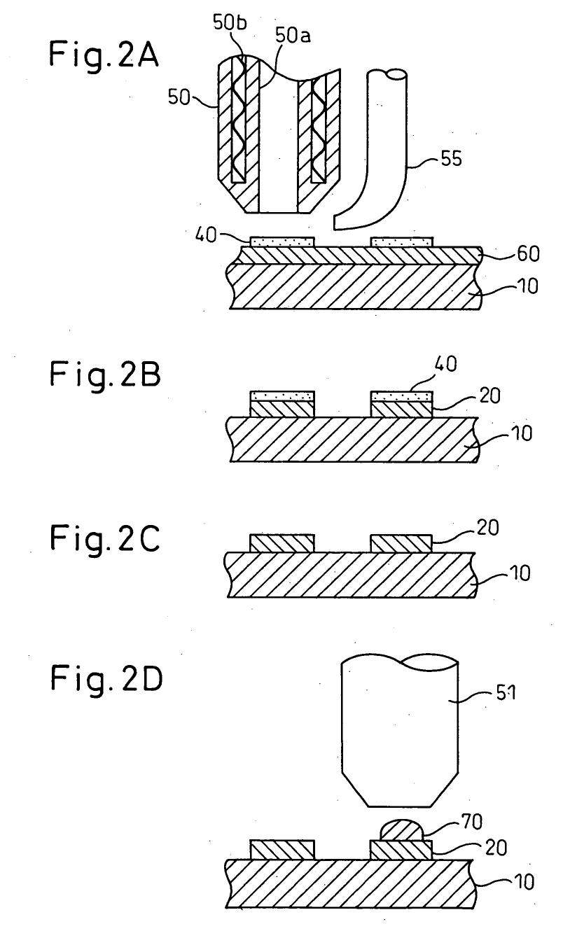

Next, referring to the views, a manufacturing method of the printed board 10 having the wiring 20 shown in FIG. 1 will be explained below. FIGS. 2A to 2D are views showing a manufacturing process for forming a pattern of the above wiring 20 by a printing method in which a printer is used. In this embodiment, the wiring pattern is formed by the method in which the printer is used. Therefore, the printer will be explained first. The printer relating to the present embodiment includes: a nozzle 50 for injecting a fused coating material 40 onto the printed board 10; a cold air outlet 55 for cooling a periphery of the nozzle 50 by cold air; a drive unit, not shown, for driving the nozzle 50; and a control unit, not shown, for outputting data to drive the nozzle 50 to the drive unit. In this connection, a sectional view showing an outline of the nozzle 50 is shown only in FIG. 2A.

The above printer uses a coating material 40, the principal component of which is paraffin. A fusion start temperature (fusion point) of this coating material 40 is, for example, 53° C. and a fusion end temperature is 55° C. to 58° C. That is, a state of fusion or coagulation of this coating material 40 is completed in the temperature range from 2° C. to 5° C. Therefore, when the temperature of the coating material 40 is changed by only 2 to 5° C., the coating material 40 can be easily fused or coagulated. In this connection, in order to fuse or coagulate the coating material 40 by a small difference in the temperature, it is preferable that a difference between the fusion start temperature and the fusion end temperature of the coating material 40 be 2° C. That the principal component of the coating material is paraffin includes the situation in which all of the coating material is made of paraffin.

In the coating material 40, paraffin may be mixed with powder material containing alumina, carbon, iron, SUS (stainless steel), SiC, Si or silicon nitride. The fusion point of the coating material 40 can be set, for example, at a temperature in the range from 18 to 100° C. As described above, the material added to paraffin can be set according to the material which becomes an object of patterning.

For example, materials described in the following items (1) to (9) can be used.

(1) Paraffin of 100 weight %

(2) Paraffin of 40 to 90 weight %, solder material powder (particle size: nano particle to several mm) of 10 to 60 weight %, further pine resin of 0 to 20 weight %

(3) Paraffin of 40 to 100 weight % and alumina powder (particle size: nano particle to several mm) of 0 to 60 weight %

(4) Paraffin of 40 to 100 weight %, SiC powder (particle size: nano particle to several mm) of 0 to 60 weight %

(5) Paraffin of 0 to 100 weight % and copper powder (particle size: nano particle to several mm) of 0 to 60 weight %.

(6) Paraffin of 40 to 100 weight % and glass powder (particle size: nano particle to several mm) of 0 to 60 weight %

(7) Paraffin of 40 to 100 weight % and carbon graphite powder (particle size: nano particle to several mm) of 0 to 60 weight %

(8) Paraffin of 0 to 95 weight % and silk printing material, the content of which is 5 to 100%

(9) Paraffin of 0 to 95 weight % and the content of green mask printing material is 5 to 100%

The molecular formula of the above paraffin is CnHm (n and m: arbitrary integers). When the value n is low, the fusion temperature is decreased. When the value n is high, the fusion temperature is increased. Accordingly, when paraffin CnHm, the value n of which is low, and paraffin CnHm, the value n of which is high, are mixed with each other, the fusion temperature is dispersed in a range. Accordingly, in order to reduce the range in which the fusion temperature is dispersed to be 2° C. to 5° C., the purity of paraffin is enhanced. Specifically, the narrower the range in which the molecular weight of paraffin is dispersed, the more the purity of paraffin is enhanced. That is, when it is desired that paraffin be fused by a temperature difference of 2° C. at room temperature, paraffin, the molecular weight distribution range of which is approximately 50 to 3000, is used. In the case of paraffin material which is fused at a temperature close to 50° C., paraffin, the molecular weight distribution range of which is 100 to 10000, is used. In the case of paraffin material which is fused at a temperature close to 90° C., paraffin, the molecular weight distribution range of which is 500 to 100000, is preferably used.

As a method of reducing the molecular weight distribution range, it is possible to use a method of refining paraffin material. Accordingly, when refinement is highly accurately carried out, the molecular weight distribution range is reduced. When the molecular weight distribution range is narrow, the purity is enhanced and the range of the fusion temperature is reduced. Therefore, it is possible to fuse or coagulate in a narrow temperature range. With respect to this material, it is possible to repeat fusion and coagulation many times. Accordingly, there is no possibility of the nozzle becoming blocked. Therefore, even when the work is interrupted, as long as the material (the coating material 40) can be heated, the quality of products can be stabilized.

The viscosity of the coating material 40 at the time of fusion is, for example, 1 mPa·s (mili-pascal second) to 3 mPa·s. This viscosity is substantially the same as that of water. Therefore, it can be said that the fluidity of the fused coating material 40 is remarkably excellent. An example of the coating material 40 having the above characteristic is Katameru chakku (Brand name, registered trademark, Thermofix, the United States registered trademark).

The nozzle 50, from which the above coating material 40 is injected, is made of ceramics (for example, a sintered body of alumina). The bore diameter of the nozzle hole 50a of the nozzle 50, that is, the bore diameter of the injection hole is approximately 30 μm to 50 μm. In the present embodiment, the nozzle 50 is designed so that the bore diameter of the nozzle 50 can be the same as the line width of the wiring 20. Further, the temperature of the nozzle 50 is set at the fusion temperature of the coating material 40. That is, the fused coating material 40 is injected from the nozzle 50. For example, in the case where a coating material 40, which starts fusing at 53° C. and is completely fused at 55° C., is used, it is preferable that the nozzle 50 and the periphery of the nozzle 50 be heated at 56° C. to 58° C. That is, it is preferable that the nozzle 50 and the periphery of the nozzle 50 be heated in the range from +20° C. to +73° C. with respect to the fusion point at the maximum.

In this nozzle 50, more particularly in the periphery of the nozzle hole 50a, a heater 50b for heating the nozzle 50 is provided. Therefore, the nozzle 50 is constantly heated at a temperature which is higher than the fusion temperature of the coating material 40 by about 10° C. to 20° C.

The drive unit conducts the action of supplying the coating material 40 from the nozzle 50, for example, the drive unit pushes out the coating material 40 from the nozzle 50 by the air pressure or by the pressure generated by a heating pump. Further, the drive unit moves the nozzle 50. Furthermore, the drive unit injects the coating material 40 from the nozzle 50. Concerning the injection timing, the nozzle 50 is driven with a PZT (piezo electric element). In this case, instead of the piezo electric element, an electromagnetic valve can be used. The drive unit described above has a capacity of driving the nozzle 50 in several tens of nanoseconds to several thousands of nanoseconds. The drive unit drives the nozzle 50 according to data inputted form the control unit. In the case of drawing a straight line, the drive unit draws the straight line while the PZT (or the electromagnetic valve) is being opened. In the case of drawing a point, the drive unit drives the nozzle 50 so that the drawing of the point can be conducted while the PZT is opened only when necessary.

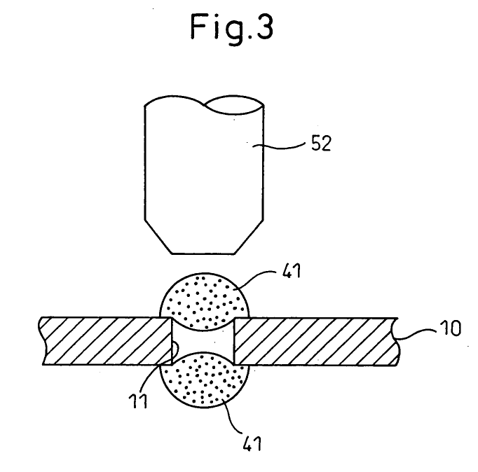

The control unit is composed of a well-known personal computer including a CPU, ROM, RAM and a hard disk. This control unit stores a wiring pattern drawing program, by which a wiring pattern is drawn on the printed board 10, and also stores a bump drawing program by which a solder bump 30 is drawn on the wiring 20. Further, the control unit stores a block drawing program by which an opening portion of the through-hole 11 (shown in FIG. 3) provided on the printed board 10 is blocked.

In this case, the drive unit compatibly uses: a fine nozzle, not shown, capable of drawing a fine line and point; a wide nozzle, not shown, capable of drawing a face; and a nozzle, not shown, capable of supplying a coating material 40 (material in which an additive agent is added to paraffin, corresponding to the solder 70 described later) of high viscosity for blocking the through-hole 11. Motions of the above many types of nozzles are programmed so that they can be simultaneously driven according to variously different shapes including fine lines, points and large faces being made up in cooperation with each other.

By the various types of nozzles, the conventional green insulating material and the printing (the common silk printing) showing the name of the product can be driven and operated simultaneously.

Although it is conventional for many steps such as a green mask step, a silk printing step and so forth to be conducted independently, it is possible for many of these steps to be conducted simultaneously in parallel with each other. Therefore, these steps can be greatly shortened. In this connection, in the green mask step and the silk printing step, the coated material is changed. Therefore, it is necessary to take care of management of the life of the material.

The constitution of the printer is as described above. With this printer, the wiring pattern (that is, the mask pattern) composed of the coating material 40 is drawn and the solder bump 30 is also drawn. Further, drawing is conducted so that an opening portion of the via-hole can be blocked or the entire hole can be blocked.

In the step shown in FIG. 2A, the printed board 10, on which the copper foil 60 has been stuck, is prepared and arranged in the printer. The printed board 10 and copper foil 60 correspond to the workpiece described in the present invention.

When the wiring pattern drawing program is executed in the control unit, the drive unit drives the nozzle 50 and the coating material 40 (for example, paraffin of 100 weight %), the thickness of which is several μm, is injected onto the copper foil 60 so as to draw the wiring pattern.

When the wiring pattern is drawn by coating the coating material 40 onto the copper foil 60 with the nozzle 50, the fused coating material 40 is injected from the nozzle 50. The temperature of the copper foil 60 is set at 48° C. to 52° C., which is lower than the fusion point of the coating material 40 by 1° C. to 5° C.

The coating material 40 is sharply changed between the fusion and coagulation by the difference of temperature of only 2° C. to 5° C. Therefore, when the coating material 40, the temperature of which is about 55° C. to 56° C., is injected from the nozzle 50 onto the copper foil 60, the temperature of the fused coating material 40 is instantaneously decreased to a temperature not more than the fusion point by the heat conduction effect of the copper foil 60. That is, a pattern of the coating material 40 drawn by the nozzle 50 becomes a wiring pattern (mask pattern) as it is. Since the fused coating material 40 is coagulated simultaneously when it is coated on the copper foil 60 as described above, there is no possibility of the coating material 40, which has been coated on the copper foil 60, being spread and oozing out on the copper foil 60. Accordingly, it is possible to draw a wiring pattern, the line width of which is substantially the same as the bore diameter of the nozzle 50. Further, when cooled air is blown out from the cooled air outlet 55 provided in the periphery of the nozzle 50, cooling can be facilitated. Therefore, it is possible to prevent the coating material 40 from oozing out. Accordingly, a sharp edge can be formed.

As described above, since the bore diameter of the injection hole of the nozzle 50 is 30 μm to 50 μm, it is possible to coat the coating material 40 by an accuracy of ±5 μm for this bore diameter. In this connection, the paraffin material is very firmly stuck onto the copper foil 60. Therefore, when the coating material 40 is coagulated, it is strongly fixed onto the copper foil 60.

When the fused coating material 40 is injected from the nozzle 50 and the nozzle 50 is driven according to the wiring pattern as described above, the wiring pattern of the coating material 40 can be formed on the copper foil 60. This wiring pattern of the coating material 40 becomes a mask for the copper foil 60.

In this connection, in the case where, for example, a wiring pattern is drawn on a printed board 10, the size of which is 300 mm×300 mm, when a coating material 40 is coated by a dot, the size of which is 50 μm, the nozzle 50 is driven by 1000000 to 5000000 times. Although it depends upon a wiring pattern, for example, a wiring pattern can be drawn in about one hour, including the moving time and the coating time of the nozzle 50.

Successively, in the step shown in FIG. 2B, the copper foil 60 is etched and an unnecessary portion of the copper foil 60 is removed. Specifically, the printed board 10 shown in FIG. 2A is dipped in a solution of ferric chloride. Due to the foregoing, a portion of the copper foil 60, on which the coating material 40 is not coated, is dissolved by the ferric chloride.

In this connection, the oxidation resistance of paraffin material with respect to the solution of ferric chloride, in which the copper foil 60 is etched, is remarkably excellent. Accordingly, when the film thickness of the coating material 40 is several μm, the oxidation resistance is sufficiently high.

In the step shown in FIG. 2C, the coating material 40 is removed from the copper foil 60. Specifically, the coating material 40 is removed as follows. Since the coating material 40 is fused and coagulated at a temperature, when water, the temperature of which is higher than the fusion end temperature (55° C. to 58° C.) of the coating material 40, is poured onto the printed board 10, the coating material 40 can be removed from the copper foil 60. In this way, the copper foil 60 can be patterned according to the wiring pattern.

In this connection, the printed board 10 may be dipped in warm water. In this case, when a surface active agent is added to the warm water, the coating material 40 can be dissolved in the water solution. Since the gravity of the coating material 40 is lower than that of water, for example, the gravity of the coating material 40 is 0.8 to 0.9, the coating material 40 floats on warm water. Therefore, it is easy to clean the printed board 10. In order to facilitate the cleaning effect, ultrasonic cleaning or hyperfine bubble cleaning is used. In addition to this, the method of introducing a cleaning agent described above is used. When a dispersing agent is added to warm water, it is possible to disperse paraffin in the solution. Unless the dispersing agent is added to warm water, when the temperature of the warm water is decreased to a value not more than the fusion temperature, the coating material 40 floats on a surface of warm water and is solidified, and a film of the coating material 40 is formed, that is, the coating material 40 is attached again. Therefore, it is necessary to pay attention to this matter.

When the coating material 40, which has come off from the printed board 10 as described above, is recovered and recycled or reused, the coating material 40 can be utilized many times.

In the step shown in FIG. 2D, the solder bump 30 is formed. In this step, in order to form the solder bump 30, a solder material 70 is used. This solder material 70 is made by mixing paraffin, solder particles, the particle size of which is sub-micron to several tens μm, and pine resin with each other. The volume ratio is, for example, paraffin 30% to 40% and solder 60% to 70%. Further, pine resin is added to the mixture in which paraffin and solder are mixed with each other by this volume ratio. The viscosity of the solder material 70 described above is higher than that of the coating material 40.

This step uses a nozzle 51, the bore diameter of which is smaller than that of the nozzle 50 used for forming the wiring pattern. The reason for this is that the solder material 70 injected onto the wiring 20 is prevented from flowing down from the wiring 20. Accordingly, the diameter of the injection port of the nozzle 51 is smaller than the width of the wiring 20. For example, the diameter of the injection port of the nozzle 51 is 20 μm.

When a solder bump drawing program is executed by the control unit, the nozzle 51 is driven by the drive unit. In this way, on the wiring 20, for example, a dot-shaped solder material 70, the size of which is 20 μm, is coated. In this case, the composition of the dot-shaped solder material 70 is as follows. The content of paraffin is 40 to 90 weight %, the content of solder material powder (particle size: nano particle to several mm) is 10 to 60 weight % and the content of pine resin is 0 to 20 weight %.

At the same time, it is possible to coat a coating material, the content of paraffin of which is 0 to 95 weight % and the content of silk printing material of which is 5 to 100 weight %. It is also possible to coat a coating material, the content of paraffin of which is 0 to 95 weight % and the content of green mask printing material of which is 5 to 100 weight %.

That is, in the same manner as that shown in FIG. 2A, the nozzle 51 is heated to a temperature not less than the fusion point of the solder material 70 and the printed board 10 is maintained at a temperature not more than the fusion point of the solder material 70. In this state, when the solder material 70 is injected onto the wiring 20 on which the solder bump 30 is to be formed, the temperature of the fused solder material 70 is instantaneously decreased to a value not more than the fusion point. Therefore, the fused solder material 70 is coagulated and formed into a dot-shape.

After that, a reflow step is executed by heating the printed board 10. Specifically, the reflow step is executed as follows. With respect to the dot-shaped solder material 70 which has been coagulated on the wiring 20, paraffin and pine resin are fused and vaporized. Further, paraffin and pine resin are made to flow away by cleaning so that only solder material can be left on the wiring 20. In this way, the dot-shaped solder bump 30 can be formed.

Accordingly, in the manner described above, the printed board 10 shown in FIG. 1 is completed.

After that, a through-hole, not shown, provided on the printed board 10 shown in FIG. 1 is blocked with the coating material 40. In this case, the composition of the coating material 40 is as follows. For example, the content of paraffin is 40 to 100 weight % and the content of alumina powder (particle size: nano particle to several mm) is 0 to 60 weight %. The content of paraffin is 40 to 100 weight % and the content of glass powder (particle size: nano particle to several mm) is 0 to 60 weight %. Referring to FIG. 3, this step will be specifically explained below. FIG. 3 is a view showing a manufacturing step successively executed after the steps shown in FIGS. 2A to 2D.

In the step shown in FIG. 3, a through-hole 11 provided on the printed board 10 is blocked by the coating material 40. In the case where green sheet processing is conducted after the wiring 20 has been formed on the printed board 10, in order to prevent foreign objects from entering the through-hole 11 formed on the printed board 10, the opening portion of the through-hole 11 is closed.

When the blockade drawing program is executed in the control unit, the drive unit drives the nozzle 52 and the coating material 40 is coated on the opening portion of the through-hole 11. That is, in the same manner as that shown in FIG. 2A, the coating material 40, which has been fused, is injected from the nozzle 52 into the opening portion of the through-hole 11. When the temperature of the neighborhood of the opening portion of the through-hole 11 is maintained at a value not more than the fusion point, the coating material is coagulated. By way of the foregoing, the lid portion 41 illustrated in FIG. 3 can be formed.

It is possible to use a coating material, the content of paraffin of which is 0 to 100 weight % and the content of copper powder (particle size: nano particle to several mm) of which is 0 to 60 weight %, so as to fill the entire through-hole 11 with the coating material. In this way, electrical conductivity can be provided.

In this connection, in the present step, the fused coating material 40 is injected into the opening portion of the through-hole 11. In this case, the composition of the coating material 40 is as follows. For example, the content of paraffin is 40 to 100 weight % and the content of alumina powder (particle size: nano particle to several mm) is 0 to 60 weight %. The content of paraffin is 40 to 100 weight % and the content of glass powder (particle size: nano particle to several mm) is 0 to 60 weight %. Therefore, it is preferable to use a coating material, the viscosity of which is higher than that of the coating material 40 used at the time of forming the wiring pattern. Concerning the nozzle 52 used in the present step, the nozzle, which has been used for drawing the wiring pattern, may be used. Alternatively, a new nozzle may be prepared and used. That is, a nozzle, the injection port of which is fitted to the size of the through-hole 11 provided on the printed board 10, may be used.

In the case where the lid portion 41, which has been formed as described before, becomes unnecessary, when only warm water, the temperature of which is higher than the fusion point of the lid portion 41, is poured onto the printed board 10, is the lid portion 41 fused and made to come off from the printed board 10.

As described above, according to the present embodiment, simultaneously when the fused coating material 40 is coated on the copper foil 60, it can be coagulated. Therefore, it is possible to prevent the coating material 40 from spreading and oozing out. That is, since the temperature range of the coating material 40 from fusion to coagulation is 2° C. to 5° C., when the temperature of the copper foil 60 is maintained at a temperature lower only by 2° C. to 5° C. than the temperature of the fused coating material, the coating material 40 can be quickly coagulated. Due to the foregoing, it is possible to form a highly accurate mask on the copper foil 60. According to the mask pattern of this mask, a workpiece can be subjected to an accurate patterning.

In the present embodiment, no organic solvent is used, which is unlike the conventional case. Therefore, it is possible to eliminate a complicated step of discarding an organic solvent. It is also possible to eliminate a step of using the organic solvent. In the same manner, since no exposure is conducted on the photo-resist by using a mask, it is possible to eliminate an exposure device and a step in which the exposure device is used.

In the present embodiment, the solder bump 30 is formed on the wiring 20. According to the conventional method, solder is printed by means of printing. Therefore, a positional shift is caused. However, according to the present embodiment, the nozzle 51 can be moved to a position, at which the solder bump 30 is formed, by the control and the drive unit. Therefore, it is possible to accurately form the solder bump 30 on the wiring 20. By the solder bump 30 formed in this way, the other electronic parts and wires can be electrically connected to the wiring 20.

Further, since the coating material 40 is coagulated by a small difference in the temperature, the lid portion 41 can be formed in the opening portion of the through-hole 11 provided on the board 10, and further the through-hole 11 can be filled up by coagulating the coating material 40 inside the through-hole 11. Due to the foregoing, no foreign objects can enter the through-hole. Since the coating material 40 can be fused and coagulated by a difference in the temperature of only 2° C. to 5° C., in the case where the lid portion 41 has become unnecessary, it can be easily removed when only the temperature is raised.

Next, the second embodiment of the present invention will be explained below. In this embodiment, only different points from those of the first embodiment will be explained below. In the present embodiment, the fused coating material 40 (for example, a foil-shaped coating material or fine powder-shaped coating material, the content of paraffin of which is 100 weight % and the particle size of which is nano particle to several mm) is not coated on the copper foil 60 as a wiring pattern but the powder-shaped coating material 40 is locally heated in the copper foil 60 so that it can be fused and coagulated on the copper foil 60 and a mask of the wiring pattern can be formed.

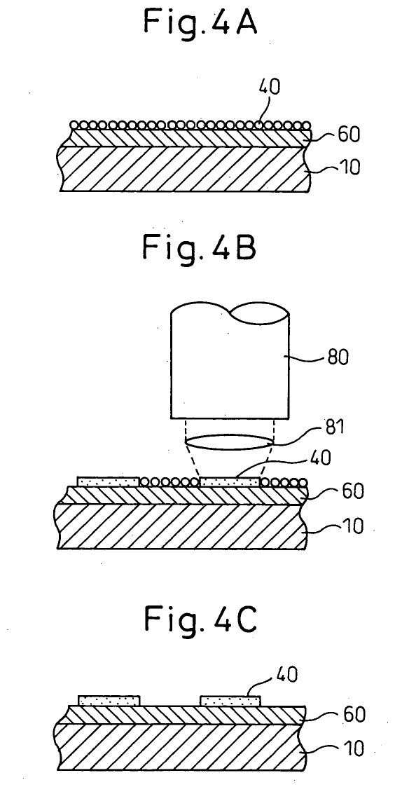

FIGS. 4A to 4C are views showing a manufacturing step for drawing a wiring pattern of the coating material 40 on the copper foil 60 by the manufacturing method of the second embodiment of the present invention. In the present embodiment, the wiring pattern is formed by a method in which laser beams are used. Therefore, first of all, an explanation will be given of the laser beam irradiation device. The laser beam irradiation device includes: a semiconductor laser 80 for irradiating laser beams; a condenser lens 81 for condensing laser beams irradiated from the semiconductor laser 80; a drive unit for driving the semiconductor laser 80; and a control unit, not shown, for outputting data, which is used for driving the semiconductor laser 80, to the drive unit.

A pulse laser beam, the period of which is constant, is irradiated from the semiconductor laser 80. Laser beams are condensed by the condenser lens 81, for example, toga spot, the diameter of which is 30 μm to 50 μm. That is, the condensed spot of the laser beams corresponds to the line width of the wiring 20 formed on the copper foil 60.

The same drive and control unit as those of the first embodiment are employed. In the present embodiment, the drive unit is used for moving the semiconductor laser 80 and driving the laser beam irradiation. In the control unit, data of the wiring pattern and the wiring pattern drawing program, in which the data is used, are stored.

The constitution of the laser beam irradiation device is as described above. With this laser beam irradiation device, a wiring pattern composed of the coating material 40 is formed on the printed board 10.

In the step shown in FIG. 4A, a printed board 10, on which a copper foil 60 is stuck, is prepared and arranged in a laser beam irradiation device. On the copper foil 60, powder-shaped coating material 40 is uniformly distributed.

In the present embodiment, the coating material 40, the characteristic of which is the same as that of the first embodiment, is used. However, in the present step, the coating material 40, which has been solidified and formed into a powder-shape, is used. The grain size of the powder-shaped coating material 40 is, for example, several μm to 10 μm. The powder-shaped coating material 40 is spread uniformly all over the copper foil 60 to a thickness of 50 μm to 100 μm. In this connection, when the powder-shaped coating material 40 is spread uniformly, a spatula or squeeze is preferably used. The powder-shaped coating material 40 is made when paraffin is coagulated and solidified. Therefore, the powder-shaped coating material 40 has no adhesion property. Accordingly, even when the coating material 40 is spread all over the copper foil 60, the coating material 40 does not stick to the copper foil 60.

Since the powder-shaped coating material 40 is fused by the heat of laser beams in a step executed later, it is preferable to use a powder-shaped coating material 40 containing paraffin to which carbon material (several weight % to 50 weight %) capable of easily absorbing laser beams is added. Due to the foregoing, the heating efficiency of the semiconductor laser 80 can be enhanced. Therefore, the powder-shaped coating material 40 can be fused uniformly and quickly.

In this connection, it is possible to use a powder-shaped coating material 40 containing paraffin to which alumina particles (several weight % to 50 weight %) having an insulation property are added. When the coating material 40 described above is used, the heating efficiency of the laser beams can be enhanced and the powder-shaped coating material 40 can be fused uniformly.

Powder, the content of paraffin of which is 40 to 90 weight % and the content of solder material powder (particle size: nano particle to several mm) of which is 10 to 60 weight %, and further the content of pine resin of which is 0 to 20 weight %, is spread all over the printed board 10 with a spatula. A portion, in which the solder needs to be fused, is irradiated with laser beams so as to fuse the powder-shaped coating-material 40. Powder in the other portions is left as it is. Therefore, it is simple to remove the powder-shaped coating material 40. In this way, the solder joining portion can be simply formed on the printed board 10.

In the step shown in FIG. 4B, the coating material 40 is fused from a portion in which the copper foil 60 becomes the wiring 20. Specifically, the step is executed as follows. When the wiring pattern drawing program is executed by the control unit, the drive unit drives the semiconductor laser 80 and the copper foil 60 is irradiated with laser beams so that the powder-shaped coating material 40 is heated. Due to the foregoing, the powder-shaped coating material 40 is heated to a temperature not less than the fusion point by the laser beams of a spot diameter condensed by the condenser lens 81. The laser beams can be condensed highly accurately by the condenser lens 81 of the laser beam source. Therefore, with respect to the target of the spot diameter of 30 μm to 50 μm, the laser beams can be irradiated to an accuracy of ±5 μm.

As described above, after the powder-shaped coating material 40 has been fused by the laser beams, the semiconductor laser 80 is moved by the drive unit in accordance with the wiring pattern. Due to the foregoing, the temperature of the coating material 40, onto which the irradiation of the laser beams has been stopped, is decreased to a value not more than the fusion point. Therefore, the coating material 40 is coagulated. That is, while the semiconductor laser 80 is irradiating the laser beams, the semiconductor laser 80 is moved. Due to the foregoing, the powder-shaped coating material 40 in a portion on the copper foil 60, which has been irradiated with the laser beams, is successively fused and coagulated and the wiring pattern can be drawn.

In this connection, the above drive unit moves the semiconductor laser 80 on the copper foil 60. However, the semiconductor laser 80 may be fixed at one position and the laser beams irradiated by the semiconductor laser 80 may conduct scanning on the copper foil 60, for example, with a reflection mirror. When the above structure is employed, it is sufficient that only the angle (posture) of the reflection mirror be changed, and the drawing time of drawing the wiring pattern can be reduced. Further, when a motion of the reflection mirror is synchronized with a motion of the printed board 10, the drawing time can be further reduced.

In the step shown in FIG. 4C, the powder-shaped coating material 40, which has not been fused in the step shown in FIG. 4B, is removed from the copper foil 60. Since the powder-shaped coating material 40 is not stuck firmly to the copper foil 60, when the printed board 10 is turned over or a blast of air is blown onto the printed board 10, the powder-shaped coating material 40 can be removed from the copper foil 60. Due to the foregoing, as shown in FIG. 4C, a mask of the wiring pattern can be formed out of the coating material 40 on the copper foil 60. After that, when the steps shown in FIGS. 2B and 2C are executed, the wiring 20 is formed on the printed board 10. When the step shown in FIG. 2D is executed, the solder bump 30 is formed on the wiring 20. In this way, the printed board 10 shown in FIG. 1 is completed. Further, when the step shown in FIG. 3 is executed, an opening portion of the through-hole 11 provided on the printed board 10 can be closed.

As described above, in the present embodiment, in the case of the powder-shaped coating material 40 which is spread all over the copper foil 60, only the coating material 40 in a portion which will become the mask is heated with the laser beams and fused and coagulated. That is, simultaneously when heating of the powder-shaped coating material 40 in a portion, which has been locally heated, is stopped, the powder-shaped coating material 40 is coagulated. Due to the foregoing, the coating material 40, which has been locally heated, can be prevented from spreading and oozing out and it becomes possible to form a highly accurate mask pattern on the copper foil 60.

In the present embodiment, since the coating material 40 is fused with the laser beams, it becomes unnecessary to provide the nozzle 50, from which the fused coating material 40 is injected, and to provide the heating means for heating the nozzle, unlike the first embodiment.

Next, the third embodiment of the present invention will be explained below. In this embodiment, only different points from those of the first embodiment described before will be explained. The present embodiment is characterized in that a three-dimensional object such as a three-dimensional block is masked with the coating material 40.

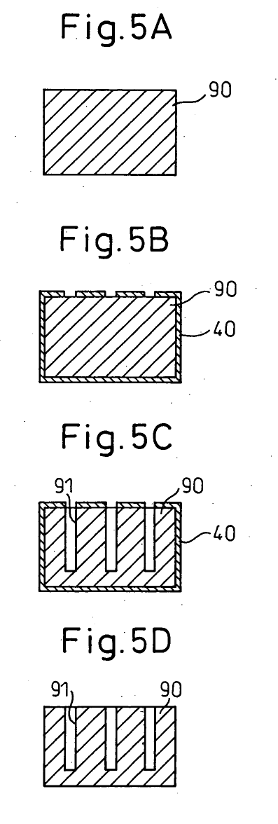

FIGS. 5A to 5D are views showing circumstances in which a metallic block is masked with the coating material 40 and worked. As shown in these views, the metallic block 90, which is a workpiece, is prepared as shown in FIG. 5A. The fused coating material 40 is injected from a nozzle onto a surface of the metallic block 90 by the same method as that of the first embodiment so that the metallic block 90 can be coated with the coating material 40. Then, the coated coating material 40 is coagulated on the surface of the metallic block 90 as shown in FIG. 5B. In this connection, since the metallic block 90 is three-dimensional, when the nozzle is moved around the periphery of the metallic block 90, the fused coating material 40 can be coated on a side of the metallic block 90.

After that, when the metallic block 90 is dipped in an etching solution, a portion of the metallic block 90, in which the coating material 40 is open, is etched by the etching solution as shown in FIG. 5C. Due to the foregoing, a groove 91 is formed on the metallic block 90. After the completion of etching, when warm water is poured onto the metallic block 90, the coating material 40 coated on the metallic block 90 is made to come off as shown in FIG. 5D. In this way, the metallic block 90, which is a three-dimensional object, can be worked.

As described above, masking can be conducted by the coating material not only on a planar object but also on a three-dimensional object. Further, it is possible to conduct patterning on the three-dimensional object.

Next, the fourth embodiment of the present invention will be explained below. In this embodiment, only different points from those of the embodiments described before will be explained. In each embodiment described above, in order to form a circuit pattern on the printed board 10, a mask is formed out of the coating material 40 in such a manner that the coating material 40 is injected onto the printed board 10, on which the copper foil 60 is stuck, from the nozzle 50 so that a wiring pattern can be drawn. However, the present invention is characterized in that a sheet made of the coating material 40 is arranged on the printed board 10 and irradiated with laser beams so that a wiring pattern can be directly drawn on the sheet. A method of drawing the wiring pattern of the present embodiment will be explained below.

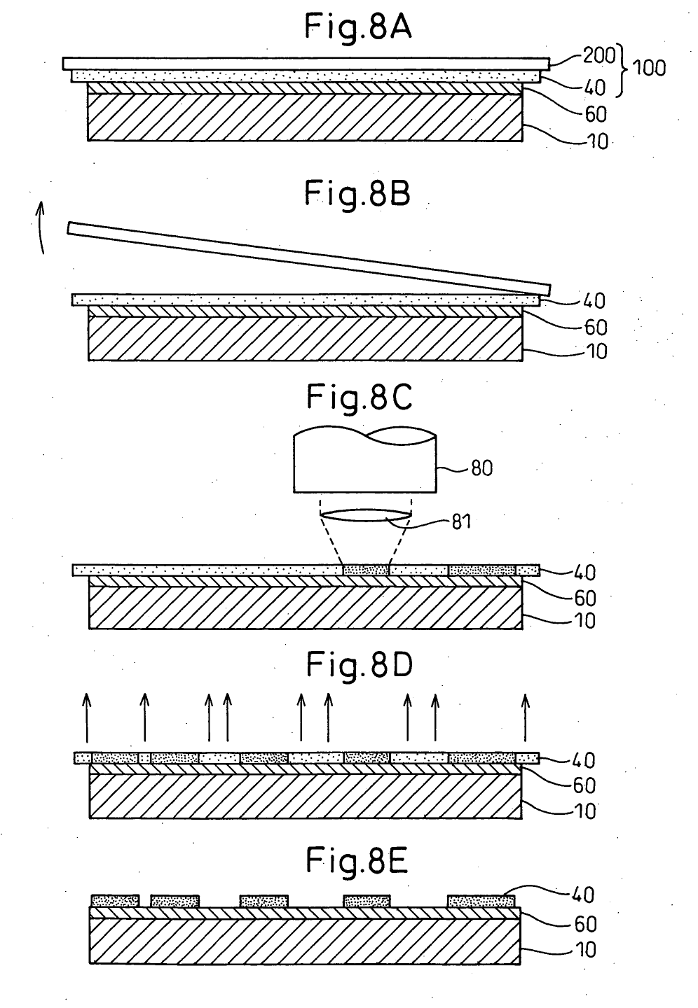

Accordingly, the present embodiment uses a drawing sheet, which is shown in FIG. 8A described later, for Y drawing a wiring pattern. Specifically, the drawing sheet includes: a PET sheet to be used as a base body which corresponds to a sheet member of the present invention; a mold releasing agent coated on one side of the PET sheet; and a coating material 40 coated on the mold releasing agent.

The PET sheet is made of resin such as polyester. The PET sheet can also be made of polyimide having a property of heat resistance, for example, a kapton sheet. Further, the PET sheet can be made of material having a high heat resistance property. In the present embodiment, the PET sheet is formed into a shape corresponding to the shape of the printed board 10. The thickness of the PET sheet is, for example, 100 μm. In this connection, it is preferable that the PET sheet be made of material capable of resisting a temperature at which the coating material 40 is fused. The present embodiment uses a well-known mold releasing agent by which the coating material 40 can be easily peeled off from the PET sheet.

The coating material 40 used in the present embodiment is the same as that used in each embodiment described before. The coating material 40 is used for drawing a wiring pattern. That is, before the wiring pattern is drawn, the coating material 40 is coated uniformly on the PET sheet and solidified. The thickness of this coating material 40 can be freely determined, for example, the thickness may be several μm to 3 mm.

Next, an explanations will be given of formation of the mask of the wiring pattern in which the above drawing sheet is used. In the present embodiment, the mask of the wiring pattern is formed with the laser beam irradiating device used in the second embodiment. FIGS. 8A to 8E are views showing a manufacturing process in which a wiring pattern of the coating material 40 is drawn on the copper foil 60 of the printed board 10 by the manufacturing method of the present embodiment.

In the step shown in FIG. 8A, the drawing sheet 100 is arranged on the printed board 10. Specifically, the printed board 10, on which the copper foil 60 is provided, and the drawing sheet 100, on which the coating material 40 is provided via a mold releasing agent, are prepared. Then, the drawing sheet 100 is set so that the copper foil 60 and the coating material 40 are opposed to each other.

In the step shown in FIG. 8B, the PET sheet 200, which is provided on the drawing sheet 100, is peeled off. As described before, on the drawing sheet 100, the PET sheet 200 and the coating material 40 are provided via the mold releasing agent. Therefore, under the condition that the coating material 40 is set on the copper foil 60, the coating material 40 is peeled off from the PET sheet 200. Due to the foregoing, the coating material 40 is set on the copper foil 60.

In the step shown in FIG. 8C, a wiring pattern is drawn with a laser beam irradiation device. That is, when the wiring pattern drawing program is executed with the laser beam irradiation device in the same manner as that shown in FIG. 4B, the semiconductor laser 80 is driven by the drive unit. Therefore, laser beams are irradiated on the copper foil 60 side and a portion of the sheet-shaped coating material 40, in which the laser beams are condensed by the condenser lens 81, is heated. Due to the foregoing, only the coating material 40 in the portion of the sheet-shaped coating material 40, to which the laser beams are irradiated, is heated to a temperature not less than the fusion point and fused.

When the semiconductor laser 80 is moved by the drive unit in accordance with the wiring pattern, the temperature of the portion, in which the laser beam irradiation has been stopped, is decreased to a value not more than the fusion point. In this way, the coating material 40 is fused to the copper foil 60. Therefore, the coating material 40 is joined strongly to the copper foil 60. Accordingly, when the semiconductor laser 80 is moved by the drive unit according to the wiring pattern while the semiconductor laser 80 is irradiating laser beams, the sheet-shaped coating material 40 corresponding to the wiring pattern is joined strongly to the copper foil 60.

In the step shown in FIG. 8D, a portion of the sheet-shaped coating material 40, which has not been irradiated with the laser beams in the step shown in FIG. 8C, is removed. For example, by utilizing a physical method such as suction, vibration or gravity, a portion of the coating material, which has not been joined yet, is peeled off and only the coating material 40, which has been drawn into the wiring pattern on the copper foil 60, is left.

In the step shown in FIG. 8E, the copper foil 60 is etched and the wiring 20 is formed. That is, when the wiring-pattern-shaped coating material 40, which has been left on the copper foil 60, is used as a mask and etching is conducted, the wiring 20 is completed. As described above, the printed board 10, on which the desired circuit pattern is formed, is completed.

As explained above, the wiring pattern portion of the sheet-shaped coating material 40, which is formed by a constant film thickness, is accurately fused locally by the semiconductor laser 80 and tightly stuck onto the copper foil 60. Therefore, it is possible to accurately form a fine shape. Compared with the conventional printing process, the above method is so simple that the number of processes can be greatly reduced. Further, it is possible to accurately form a desired pattern such as a mask.

Next, the fifth embodiment of the present invention will be explained below. In this embodiment, only different points from those of the embodiments described before will be explained. The present embodiment is characterized in that the copper foil 60 on the printed board 10 is subjected to patterning according to the wiring pattern with the drawing sheet 100 described above, and the solder bump 30 is formed in a desired portion in the wiring pattern. An explanation will be given of the wiring pattern drawing method of the present embodiment.

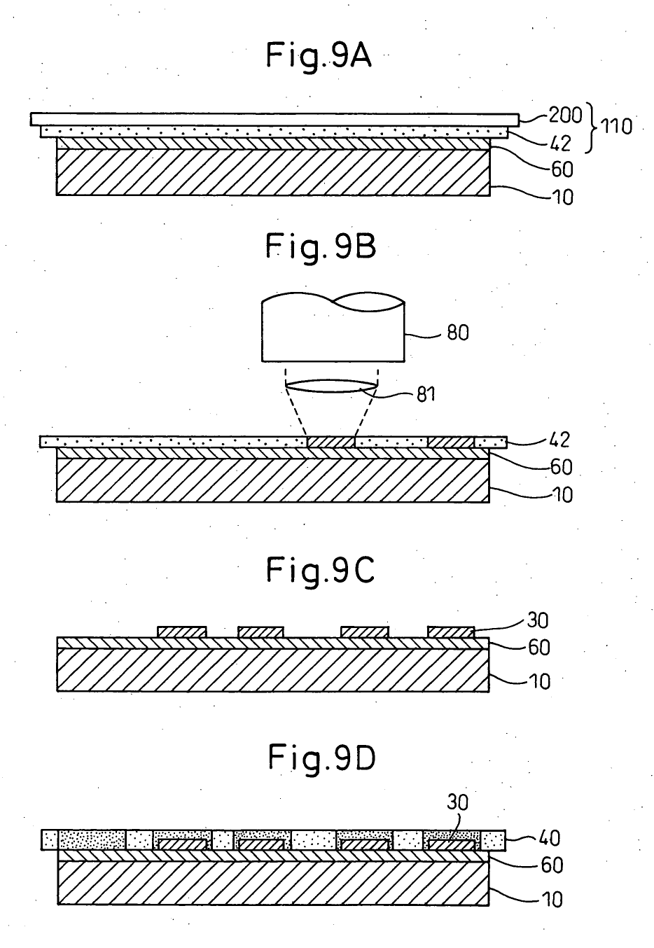

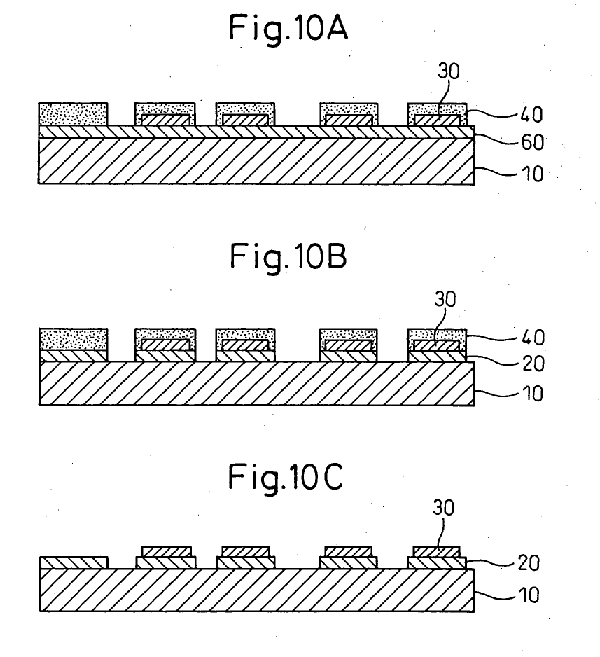

FIGS. 9A to 9D are views showing a manufacturing process for drawing a wiring pattern of the solder bump 30 and the coating material 40 on the copper foil 60 of the printed board 10. FIGS. 10A to 10c are views showing manufacturing processes successively executed after the manufacturing process shown in FIGS. 9A to 9D.

In the step shown in FIG. 9A, a drawing sheet 110 is prepared and arranged on the copper foil 60 on the printed board 10. In the present step, the drawing sheet 110 is used on which the coating material 42, into which lead free solder is mixed, is provided. The coating material 42, into which lead-free solder is mixed, is coated on the PET sheet 200 via the mold releasing agent in the same manner as that described before. In the same manner as that of the step shown in FIG. 8B, only the PET sheet 200, which is provided on the drawing sheet 110, is peeled off. Therefore, the coating material 42 is set on the copper foil 60.

In the step shown in FIG. 9B, a pattern of the solder bump 30 is drawn with the laser beam irradiation device. In this step, in the same manner as that shown in FIG. 8C, when the drawing program of the solder bump 30 is executed with the laser beam irradiation device, the semiconductor laser 80 is driven by the drive unit. Therefore, only a portion of the sheet-shaped coating material 42 corresponding to the solder bump 30 is fused and joined to the copper foil 60, so that the portion of the sheet-shaped coating material 42 can be temporarily fixed onto the copper foil 60.

In the step shown in FIG. 9C, in the same manner as that shown in FIG. 8C, a portion of the sheet-shaped coating material 42, which has not been joined to the copper foil 60, is peeled off. Then, the printed board 10 is heated and the solder bump 30, which has been temporarily fixed, is joined strongly to the copper foil 60.

In the step shown in FIG. 9D, the drawing sheet 100 is put on the copper foil 60 on which the solder bump 30 is provided. Then, the wiring pattern is drawn with the laser beam irradiation device. In this step, the drawing sheet 100, which is composed of the coating material 40 with which the solder material is not mixed, is put on the copper foil 60. Then, only the PET sheet on the drawing sheet 100 is peeled off and the wiring pattern is drawn in the same manner as that shown in FIG. 8C. At this time, the wiring pattern is drawn so that the width of the wiring pattern can be larger than the solder bump 30. The reason for this is as follows. It is necessary that the solder bump 30 be surely arranged on the wiring 20. In this connection, in order to make sure of this, laser beams are irradiated twice on the periphery of the solder bump 30.

In the step shown in FIG. 10A, in the same manner as that shown in FIG. 8D, a portion of the coating material 40 except for the wiring pattern is removed. In the step shown in FIG. 10B, in the same manner as that shown in FIG. 8E, the wiring 20 is formed by etching the copper foil 60.

In the step shown in FIG. 10C, in the same manner as that shown in FIG. 2C, the coating material 40, which is provided on the copper foil 60 formed into a wiring pattern shape is removed. Further, the coating material 40, which is provided so that it can wrap the solder bump provided on the copper foil 60, is also removed. Due to the foregoing, the same product as that shown in FIG. 1 can be completed.

The circuit pattern can be formed on the printed board 10 by this method. Further, the solder bump 30 can be formed on the wiring 20. According to the method concerned, since the solder bump 30 is previously formed and then the wiring pattern is formed, the manufacturing process can be greatly simplified.

Next, the sixth embodiment of the present invention will be explained below. In this embodiment, only different points from those of the embodiments described before will be explained. This embodiment is characterized in that the solder bump 30 is formed with the drawing sheet 110 at a desired position on the wiring pattern formed on the printed board 10.

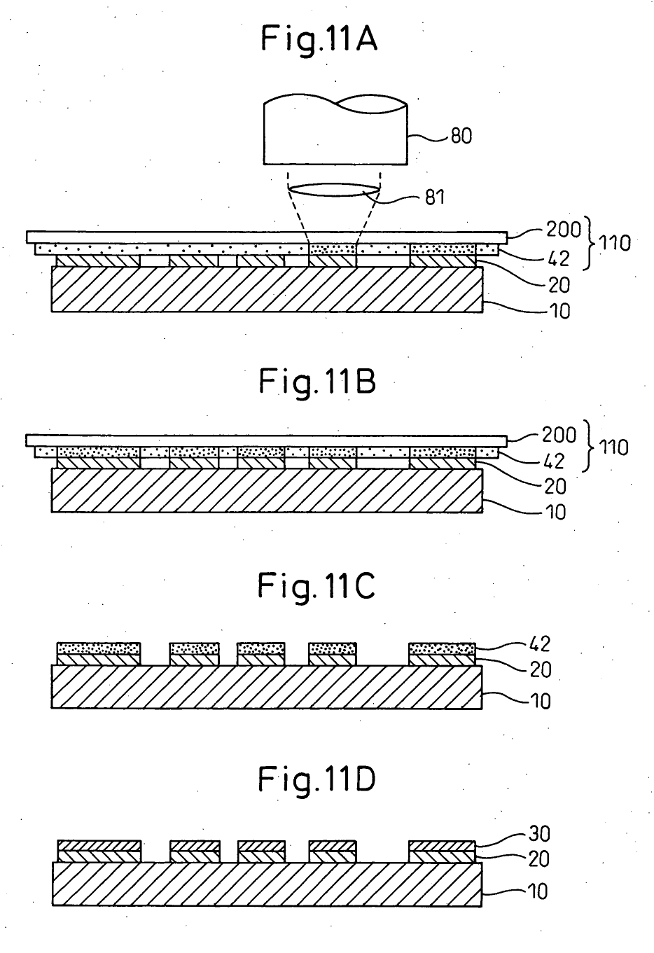

FIGS. 11A to 11D are views showing a manufacturing process of forming the solder bump 30 on the wiring pattern. In this embodiment, with the laser beam irradiation device used for the above second embodiment, the solder bump 30 is formed on the wiring pattern.

In the step shown in FIG. 11A, a pattern of the solder bump 30 is drawn on the wiring pattern. In order to draw the pattern of the solder bump 30 on the wiring pattern, first, a drawing sheet 110, which is provided with the coating material 42 into which the solder material is mixed, is prepared. Then, the drawing sheet 110 is put on the printed board 10 so that the coating material 42 concerned and the wiring pattern can be opposed to each other. Successively, a pattern of the solder bump 30 is drawn on the wiring pattern with the laser beam irradiation device. At this time, laser beams are directly irradiated to the PET sheet by the semiconductor laser 80. Therefore, the laser beams, which have passed through the PET sheet 200, are irradiated to the coating material 42. Due to the foregoing, a portion of the coating material 42, which is irradiated with the laser beams, is temporarily fixed onto the wiring pattern.

In the step shown in FIG. 11B, for example, in the same manner as that shown in FIG. 8B, the PET sheet 200 is peeled off from the coating material 42. In this connection, as described before, since the mold releasing agent is provided, the coating material 42 can be easily peeled off from the PET sheet 200. In the step shown in FIG. 11C, a portion of the coating material 42 except for the temporarily fixed portion is removed. In the present embodiment, in the same manner as that shown in FIG. 2C, the coating material 42 is removed by pouring warm water on it.

In the step shown in FIG. 11D, when the coating material 42 is heated, the solder material is fixed to the wiring 20 and the solder bump 30 is formed. That is, at the stage in which the step shown in FIG. 11C has been finished, the coating material 42 formed on the wiring pattern is temporarily fixed. Therefore, the coating material 42 is not joined strongly to the copper foil 60 composing the wiring pattern. Accordingly, when heating is conducted in this step, the solder material included in the coating material 42 is joined strongly to the copper foil 60. In this way, the solder bump 30 is completed on the wiring 20.

As explained above, a pattern of the solder bump 30 can be directly drawn on the wiring pattern with the drawing sheet 110. Even when this method is employed, the pattern of the solder bump 30 can be formed.

Next, the seventh embodiment of the present invention will be explained below. In this embodiment, only different points from those of the sixth embodiment described before will be explained. This embodiment is characterized in that after the PET sheet 200 has been peeled off from the drawing sheet 110, the coating material 42 is patterned to the pattern of the solder bump 30.

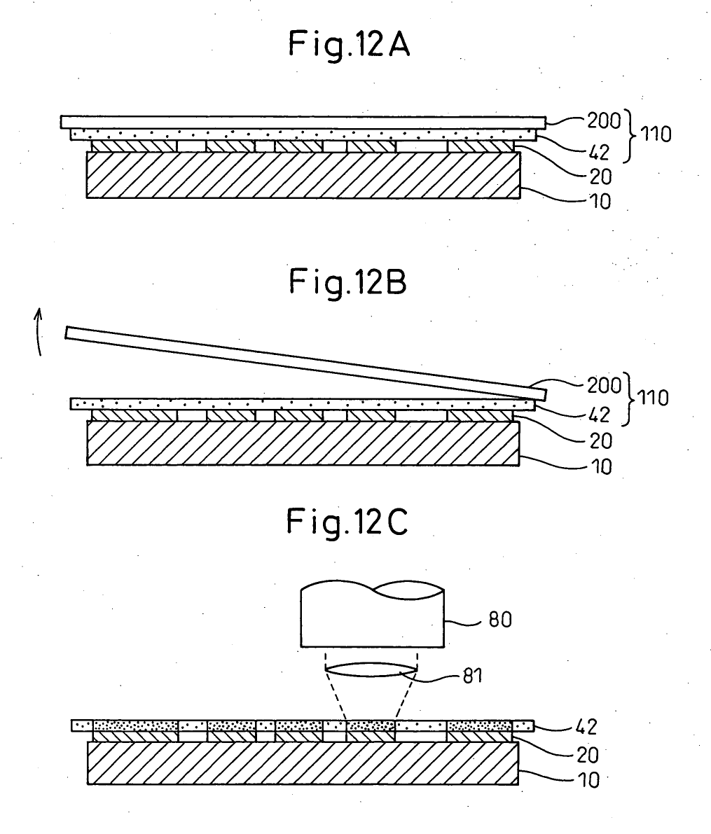

FIGS. 12A to 12C are views showing a manufacturing process in which the solder bump 30 is formed on the wiring pattern in the present embodiment. In the step shown in FIG. 12A, a drawing sheet 110 is prepared. Then, the drawing sheet 110 is put on the printed board 10 so that the coating material 42 coated on the drawing sheet 110 can be opposed to the wiring pattern. In the step shown in FIG. 12B, in the same manner as that shown in FIG. 8B, the PET sheet 200 is peeled off from the sheet-shaped coating material 42.

In the step shown in FIG. 12C, a pattern of the solder bump 30 is drawn on the wiring pattern with the laser beam irradiation device. Due to the foregoing, a portion of the coating material 42, which will become the solder bump 30, is temporarily fixed onto the wiring pattern.

After that, in the same manner as that shown in FIG. 11C, a portion of the coating material 42 except for the temporarily fixed portion is removed. Then, in the same manner as that shown in FIG. 11D, the coating material 42 is subjected to heat treatment so that the solder material can be joined strongly to the wiring 20. In this way, the solder bump 30 is formed.

As explained above, after the PET sheet 200 has been peeled off from the coating material 42, patterning can be conducted in such a manner that the pattern of the solder bump 30 is formed on the coating material 42. According to this method, at the time of irradiating the laser beams, when the laser beams are directly irradiated onto the coating material 42 without interposing the PET sheet 200, it is possible to enhance the accuracy of the focal position of the laser beams. Therefore, soldering can be conducted with high accuracy.

Next, the eighth embodiment of the present invention will be explained below. In this embodiment, only different points from those of the embodiments described before will be explained. This embodiment is characterized as follows. In the case where the solder bump 30 is formed at a desired position on the wiring pattern, when the drawing sheet 110, which is set on the printed board 10, is moved, the coating material 42 on the PET sheet 200 is effectively utilized. The manufacturing method of the present embodiment will be explained below.

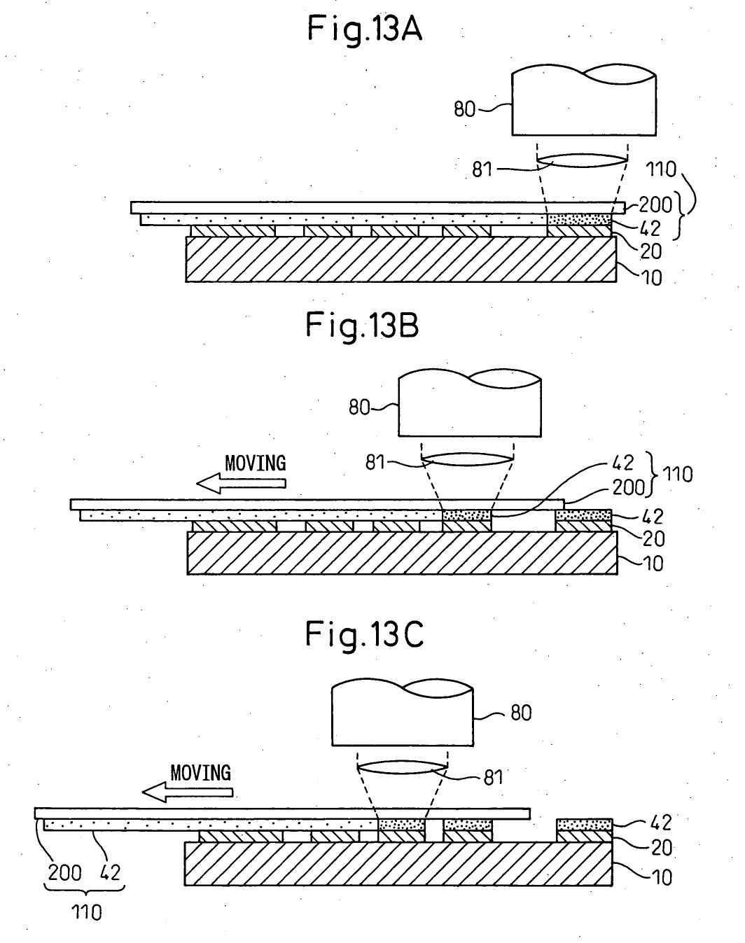

FIGS. 13A to 13C are views showing manufacturing processes of forming a solder bump on the wiring pattern. In the step shown in FIG. 13A, the solder bump 30 is temporarily fixed at one position in the wiring pattern. In order to fix the solder bump 30 at one position, a drawing sheet 110 is first prepared. The thus prepared drawing sheet 110 is arranged in a moving device, not shown, which is capable of moving the drawing sheet 110 on the printed board 10. Into this moving device concerned, the size of the coating material 42 of the drawing sheet 110 and a positional parameter such as a coordinate are previously inputted.

Then, the drawing sheet 110 is put on the printed board 10 so that the coating material 42, which is coated on the drawing sheet 110, and the wiring pattern are opposed to each other, more particularly, so that an end portion of the coating material 42 on the PET sheet 200 is located at a position on the wiring pattern where the solder bump 30 is to be formed. After that, laser beams are irradiated from the semiconductor laser 80 and the coating material 42 is temporarily fixed onto the wiring pattern.

In the step shown in FIG. 13B, the coating material 42 is temporarily fixed at a position different from the position where the coating material 42 is temporarily fixed in the step shown in FIG. 13A. Specifically, the drawing sheet 110 is moved by the moving device so that an end portion of the coating material 42 on the PET sheet is located at a position where the next solder bump 30 is going to be formed. Then, laser beams are irradiated from the semiconductor laser 80 and the coating material 42 is temporarily fixed on the wiring pattern.

In the step shown in FIG. 13C, the drawing sheet 110 is moved by the moving device and the coating material 42 is temporarily fixed onto the wiring pattern in the same manner as that shown in FIG. 13B.

After that, the drawing sheet 110 is moved by the moving device so that the end portion of the coating material 42 on the PET sheet 200 is located at a position where the solder bump 30 is formed on the wiring pattern. When the steps shown in FIGS. 13A to 13C are repeated, patterning is conducted on the coating material 42 which becomes the solder bump 30.

After that, when heating is conducted on the coating material 42 in the same manner as that shown in FIG. 11D, the solder material in the coating material 42 is joined strongly to the copper foil 60. In this way, it is possible to form the solder bump 30.

As explained above, the present embodiment is characterized in that the drawing sheet 110 is moved, the end portion of the coating material 42 is irradiated with laser beams and the coating material 42 to become the solder bump 30 is temporarily fixed onto the wiring pattern. Due to the foregoing, the coating material 42 on the PET sheet 200 can be effectively utilized.

Next, the ninth embodiment of the present invention will be explained below. In this embodiment, only different points from those of the embodiments described before will be explained. As described above, soldering is conducted on the wiring 20 as follows. Laser beams are irradiated onto the sheet-shaped coating material 42 so as to temporarily fix the sheet-shaped coating material 42. After that, heating is conducted so that soldering can be accomplished. However, on the printed board 10, various wiring patterns such as a fine circuit and a wiring, in which a high intensity of electric current flows, is formed. Accordingly, it is preferable that a solder bump 30 corresponding to each type of wiring be formed on the printed board 10.

Therefore, the present embodiment is characterized in that when a portion of the coating material 42, which becomes the solder bump 30, is temporarily fixed onto the wiring pattern, a semiconductor laser, the output of which is different according to the size of the solder bump 30 to be formed, is used. It is also possible to apply the present embodiment to a mixed type printed board 10 having a plurality of circuits, the electric current capacities of which are different from each other.

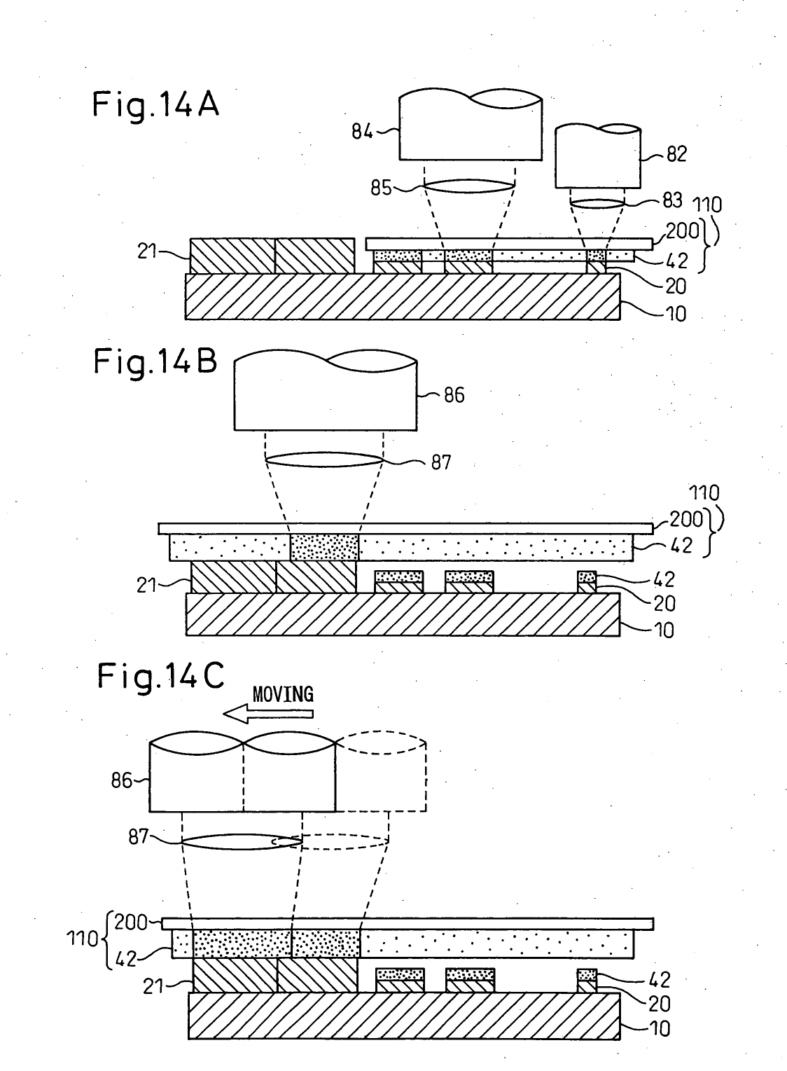

FIGS. 14A to 14C are views showing a state in which the coating material 42 is temporarily fixed with a different semiconductor laser. FIG. 14A is a view showing a state in which a portion of a fine wiring pattern, which becomes the solder bump 30, is temporarily fixed.

As shown in this view, with respect to the fine wiring pattern, a drawing sheet 110 is prepared which has a coating material 42, the thickness of which is capable of forming a solder bump 30 corresponding to the fine wiring pattern. Further, the coating material 42 is irradiated with laser beams by a semiconductor laser 82, the output power of which is low. In order to conduct patterning on the fine solder bump 30, it is preferable to use a fine condenser lens 83 corresponding to the above semiconductor laser 82.

With respect to the wiring, which is not so fine, in which such a high intensity of electric current flowing in a bus-bar 21 does not flow, the coating material 42 is irradiated with laser beams by a semiconductor laser 84, the output of which is higher than that of the above semiconductor laser 82. In this case, it is preferable to use a condenser lens 85 corresponding to the semiconductor laser 84.

As described above, with respect to the wiring pattern of the fine circuit or the middle-sized circuit, when the above semiconductor lasers 82, 84 are used combined with each other, the coating material 42 is temporarily fixed onto the wiring pattern and heating is conducted. In this way, the solder bump 30 can be formed.

FIG. 14B is a view showing a state in which a portion of the coating material 42, which becomes the solder bump 30, is temporarily fixed to the bus-bar 21. The bus-bar 21 is formed of copper foil, the thickness of which is greater than that of the wiring pattern in the above fine circuit.

As shown in FIG. 14B, with respect to the bus-bar 21, a drawing sheet 110 is prepared, which has a coating material 42, the thickness of which is the same as the thickness by which the solder bump 30 corresponding to the bus-bar 21 can be formed, that is, a drawing sheet 110 is prepared, which has a coating material 42, the thickness of which is greater than the thickness of the coating material 42 shown in FIG. 14A. Further, the coating material 42 is irradiated with laser beams by the semiconductor laser 86, the output power of which is higher than that of the above semiconductor lasers 82, 84. Even in this case, it is preferable to use a condenser lens 87 corresponding to the semiconductor laser 86.

In the case where the solder bump 30 is formed corresponding to the type of the wiring pattern as described above, laser beams are irradiated from the semiconductor laser 82, 84, 86 corresponding to the sheet-shaped coating material 42 according to the size of the solder bump 30 to be formed.

FIG. 14C is a view showing a state in which a portion of the coating material 42, which becomes the solder bump 30, is temporarily fixed in a wide range of the bus-bar 21. In this case, when the semiconductor laser 86 is moved by the drive unit of the laser beam irradiating device, the coating material 42 can be temporarily fixed in the wide range on the bus-bar 21.

As described above, when the thickness of the coating material 42 is changed according to the wiring pattern corresponding to the type of the circuit formed on the printed board 10 and also when the semiconductor laser 82, 84, 86 corresponding to the wiring pattern is used, the solder bump 30 can be formed highly accurately on the wiring pattern.

Next, the tenth embodiment of the present invention will be explained below. In this embodiment, only different points from those of the embodiments described before will be explained. In the ninth embodiment described before, with respect to the wiring, the size of the bus-bar of which is large, the coating material 42 is temporarily fixed onto the bus-bar 21 by moving the semiconductor laser 86. However, the present embodiment is characterized in that a large semiconductor laser is used and the coating material 42 is temporarily fixed without moving the large semiconductor laser concerned.

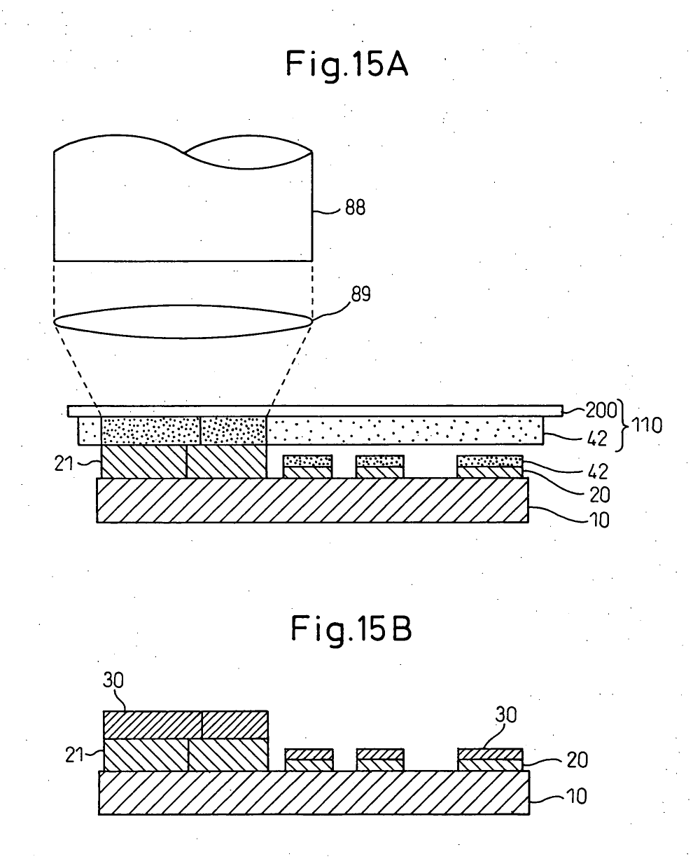

FIGS. 15A and 15B are views showing a manufacturing process of manufacturing a solder bump 30 with the large semiconductor laser in the present embodiment. In the step shown in FIG. 15A, the coating material 42 is temporarily fixed onto the bus-bar 21. Specifically, a drawing sheet 110 is prepared which has the coating material 42, at the thickness of which, the solder bump 30 corresponding to the size of the bus bar 21 can be formed. Further, a laser beam irradiation device is prepared which has a large semiconductor laser 88 capable of temporarily fixing the coating material 42 onto the bus-bar 21 only by irradiating laser beams, without moving the bus-bar 21.

Then, the semiconductor laser 88 is arranged on the bus-bar 21 of the printed wiring board 10. Laser beams are irradiated from the semiconductor laser 88 and condensed by the condenser lens 89 so that the coating material 42 can be irradiated with the laser beams. Due to the foregoing, the coating material 42 is temporarily fixed onto the bus-bar 21. Concerning the bus-bar 21, in a portion except for the portion shown in FIG. 15A, the coating material 42 is temporarily fixed in the same manner as that described before.

After that, in the step shown in FIG. 15B, when the coating material 42, which is temporarily fixed onto the bus-bar 21, is heated in the same manner as that of the step shown in FIG. 11D, the solder bump 30 is formed on the bus-bar 21.

As explained above, when the large semiconductor laser 88 is used according to the portion in which the solder bump 30 is going to be formed, the coating material 42 can be temporarily fixed without moving the semiconductor laser 88 while irradiating the laser beams.

Finally, another embodiment will be explained below. A principal component of the coating material 40 or the solder material 70 described before is paraffin. However, the principal component of the coating material 40 or the solder material 70 may be polyethylene glycol.

In the first and the second embodiment, the steps including the step of the start to the step of closing the through-hole 11 of the printed board 10 are executed. However, the steps including the step of the start to the step of forming the wiring 20 by drawing the wiring pattern may be executed. In the same manner, the steps including the step of the start to the step of forming the solder bump 30 may be executed. Further, it is possible to execute a step of forming the lid portion 41 without forming the solder bump 30.

In the first and the second embodiment, only one wiring layer 20 is formed on the printed board 10. However, multiple wiring layers may be formed by the method described above.

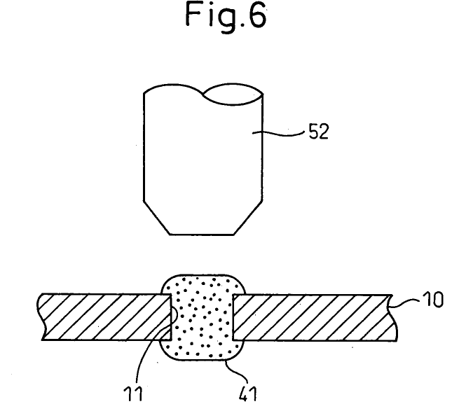

In the first embodiment, the lid portion 41 is formed in the opening portion of the through-hole 11 of the printed board 10. However, this through-hole 11 may be filled with the coating material 40. FIG. 6 is a view showing a step of filling the coating material 40 into the through-hole 11 on the printed board 10. As shown in this view, the fused coating material 40 is injected from the nozzle 52 into the through-hole 11 provided on the printed board 10. Since the printed board 10 is maintained at a temperature not more than the fusion point, the coating material 40 coated in the through-hole 11 is coagulated in the through-hole 11. In this way, the through-hole 11 can be filled with the coating material 40.

In each embodiment described above, sizes and pieces of positional information of the printed board and the workpiece to be worked are previously stored in the control unit. In addition to this, the printed board 10 and the workpiece may be photographed with a camera and subjected to image processing so that that positions of the wiring 20 and the through-hole 11 can be accurately determined.

In the first and the second embodiments, the coating material 40 is drawn on the copper foil 60 so that the copper foil 60 can be etched. In the case where a workpiece is patterned, a dot is formed in the workpiece and a picture is drawn in the workpiece, it is possible to apply the method of each embodiment described above. Examples of the workpiece are paper, cloth, metallic foil and metallic sheets.

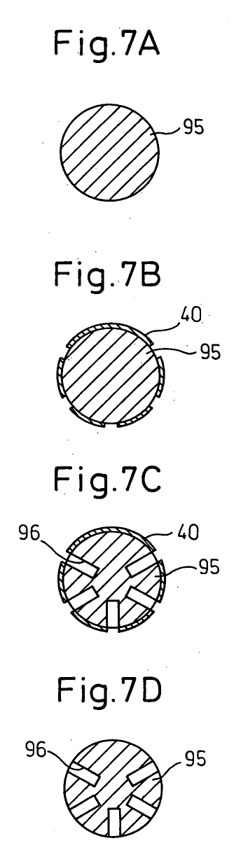

In the third embodiment, a mask is formed on a block-shaped object. However, as shown in FIGS. 7A to 7D, the coating material 40 may be formed on a spherical face of a sphere and, for example, etching may be conducted. FIGS. 7A to 7D are views showing a state in which masking of the coating material 40 is conducted on a sphere. As shown in this view, a sphere 95, which is a workpiece, is prepared as shown in FIG. 7A. A spherical face of the sphere 95 is subjected to masking as shown in FIG. 7B. Then, the sphere 95 is dipped in an etching solution and etched so as to form a groove 96 as shown in FIG. 7C. After that, warm water is poured onto the sphere 95 and the coating material 40, which is coagulated on the side of the sphere 95, is fused and removed as shown in FIG. 7D. As described above, the spherical face of the sphere 95 may be masked with the coating material 40 and patterning may be conducted.

In the eighth embodiment, an end portion of the coating material 42 coated on the PET sheet 200 is irradiated with laser beams. However, the following method may be adopted. When the drawing sheet 110 is moved by the moving device, a portion of the coating material 42, which is not irradiated with laser beams, is moved to a position where the solder bump 30 is to be formed. Then, laser beams are irradiated so that the coating material 42 can be temporarily fixed.

In the ninth embodiment, in the same manner as that of the eighth embodiment, the coating material 42 may be effectively utilized by moving the drawing sheet 110.

While the invention has been described by reference to specific embodiments chosen for purposes of illustration, it should be apparent that numerous modifications could be made thereto by those skilled in the art without departing from the basic concept and scope of the invention.

1. A manufacturing method of a workpiece in which a mask is formed in the workpiece with a coating material and the workpiece is worked with the mask, the method comprising:
a step of forming a mask-pattern-shaped mask on the work-piece when a fused coating material is injected from a nozzle to the workpiece, the temperature of which is lower than a fusion start temperature of the coating material, so as to coat the coating material on the workpiece and when the coating material is coagulated;
a step of conducting patterning on the workpiece according to the mask; and
a step of removing the mask from the workpiece when the mask is heated and fused.

2. A manufacturing method of a workpiece in which a mask is formed on the workpiece with a powder-shaped coating material and the workpiece is worked with the mask, the method comprising:
a step of spreading the powder-shaped coating material on a surface of the workpiece;
a step of forming a mask-pattern-shaped mask when the powder-shaped coating material, which is spread on a surface of the workpiece, is locally heated and fused in a portion which becomes the mask and when the coating material in the locally heated position is coagulated by moving the locally heated position;
a step of removing the powder-shaped coating material left on the workpiece;
a step of patterning the workpiece according to the mask; and
a step of heating and fusing the mask and removing the mask from the workpiece.

3. A manufacturing method of a workpiece according to claim 1, wherein a difference between a fusion start temperature and a fusion end temperature of the coating material is not more than 5° C.

4. A manufacturing method of a workpiece according to claim 1, further comprising:
a step of preparing a solder material in which solder is added to the coating material and coating the fused solder material on the workpiece, which has been patterned, in a dot-shape and coagulating it; and
a step of fusing the coating material in the solder material by heating the workpiece and joining the solder contained in the solder material to the workpiece, wherein these steps are executed after the completion of the mask removing step.

5. A manufacturing method of a workpiece according to claim 1, further comprising:
a step of closing an opening portion of a through-hole provided in the workpiece by injecting the fused coating material from a nozzle into the opening portion of the through-hole and by coagulating it in the case where the through-hole is provided in the workpiece, wherein this step is executed after the mask removing step is completed.

6. A manufacturing method of a workpiece according to claim 1, further comprising:
a step of closing a through-hole with a coating material by injecting the fused coating material from a nozzle into the through-hole and by coagulating it in the case where the through-hole is provided in the workpiece, wherein this step is executed after the mask removing step is completed.

7. A manufacturing method of a workpiece in which a mask is formed in the workpiece with a coating material and the workpiece is worked with the mask, the method comprising:
a step of preparing a drawing sheet on which the coating material is coated on a sheet member;
a step of arranging the drawing sheet on the workpiece so that the workpiece and the coating material are opposed to each other;
a step of removing the sheet member from the drawing sheet arranged on the workpiece;
a step of locally heating and fusing the coating material which is arranged on a surface of the workpiece and located in a portion in which the mask is to be formed, and forming a mask-pattern-shaped mask when the coating material, which has been heated, is coagulated by moving the position to be locally heated;
a step of patterning the workpiece according to the mask; and
a step of removing the mask from the workpiece by heating and fusing the mask.

8. A manufacturing method of a workpiece in which a solder bump is directly drawn on the workpiece with a coating material containing a solder material, the method comprising:
a step of preparing a drawing sheet on which the coating material containing the solder material is coated on a sheet member;
a step of arranging the drawing sheet on the workpiece so that the workpiece and the coating material containing the solder material are opposed to each other;
a step of removing only the sheet member from the drawing sheet arranged on the workpiece;
a step of temporarily fixing the coating material containing the solder material to the workpiece by locally and directly heating and fusing a portion, in which the solder bump is to be formed, of the coating material containing the solder material arranged on a surface of the workpiece; and
a step of forming the solder bump by fixing the solder material contained in the coating material to the workpiece when the coating material containing the solder material arranged on the workpiece is heated.

9. A manufacturing method of a workpiece according to claim 8, wherein the step of temporarily fixing the coating material containing the solder material includes a step of removing a portion of the coating material containing the solder material which has not been locally heated.

10. A manufacturing method of a workpiece according to claim 8, further comprising:
a step of preparing a drawing sheet on which the coating material not containing the solder material is coated on the sheet member after the solder bump has been formed on the workpiece;
a step of arranging the drawing sheet on the workpiece so that the workpiece and the coating material not containing the solder material are opposed to each other and removing only the sheet member from the drawing sheet;
a step of forming a wiring-pattern-shaped mask when a portion of the coating material not containing the solder material, which becomes a mask, is locally and directly heated and fused so that the solder bump is wrapped by the coating material, and when the coating material not containing the solder material in the heated portion is coagulated by moving the locally heated portion;
a step of patterning the workpiece into a mask-pattern-shape according to the mask; and
a step of removing the mask from the workpiece by heating and fusing the mask.

11. A manufacturing method of a workpiece in which a solder bump is directly drawn on the workpiece with a coating material containing a solder material, the method comprising:
a step of preparing a drawing sheet on which the coating material is coated on a sheet member;
a step of arranging the drawing sheet on the workpiece so that the workpiece and the coating material are opposed to each other;
a step of temporarily fixing the coating material containing the solder material to the workpiece when a portion of the coating material, in which the solder bump is to be formed, is locally and directly heated and fused from a side opposite to the coating material in the sheet member; and
a step of forming the solder bump by fixing the solder material contained in the coating material to the workpiece when the coating material containing the solder material on the workpiece is subjected to heat treatment.

12. A manufacturing method of a workpiece in which a solder bump is directly drawn on a workpiece with a coating material containing a solder material, the method comprising:
a step of preparing a drawing sheet on which the coating material is coated on a sheet member;
a step of arranging the drawing sheet on the workpiece so that the workpiece and the coating material are opposed to each other;
a step of removing only the sheet member from the drawing sheet arranged on the workpiece;
a step of temporarily fixing the coating material containing the solder material to the workpiece when a portion of the coating material, in which the solder bump is to be formed, is locally heated and fused; and
forming the solder bump by fixing the solder material contained in the coating material to the workpiece when the coating material containing the solder material on the workpiece is subjected to heat treatment.

13. A manufacturing method of a workpiece according to claim 12, wherein the step of temporarily fixing the coating material containing the solder material to the workpiece includes a step of temporarily fixing the coating material at a position where the solder bump is to be formed when a not heated portion of the coating material is moved to the position where the solder bump is to be formed by moving the sheet material.

14. A manufacturing method of a workpiece according to claim 2, wherein the coating material concerned is locally heated when laser beams irradiated from the semiconductor laser are condensed onto the coating material by the condenser lens in the step of heating the coating material.

15. A manufacturing method of a workpiece according to claim 1, wherein a difference between the fusion start temperature of the coating material and the fusion end temperature is in the range from 18° C. to 100° C.

16. A manufacturing method of a workpiece according to claim 1, wherein a principal component of the coating material is paraffin or polyethylene glycol.
